(19) United States
(12) Patent Application Publication
(10) Pub. No.: US 2011/0101328 A1
(43) Pub. Date: May 5, 2011

(54) Organic Electroluminescent Device

(75) Inventors: Joachim Kaiser, Darmstadt (DE); Horst Vestweber, Gilserberg (DE); Simone Leu, Dittelsheim-Hessloch (DE)

(73) Assignee: Merck Patent GmbH, Darmstadt (DE)

(21) Appl. No.: 13/001,645

(22) PCT Filed: Nov. 18, 2009
(86) PCT No.: PCT/EP2009/008199

§ 371 Date: Dec. 28, 2010

(30) Foreign Application Priority Data
Dec. 17, 2008 (DE) 10 2008 063 490.5

(51) Int. Cl. H01L 51/54; H01L 51/56

(52) U.S. Cl. 257/40; 438/29; 257/E51.028; 257/E21.499

(57) ABSTRACT

The present invention relates to white-emitting organic electroluminescent devices which comprise at least one phosphorescent emitter and at least one ketone derivative as matrix material in at least one emitting layer.

The present invention relates to white-emitting organic electroluminescent devices which comprise at least one layer comprising at least one phosphorescent dopant.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. A development in the area of organic electroluminescent devices are white-emitting OLEDs. These can be employed either for monochromic-white displays or with coloured filters for full-colour displays. They are furthermore suitable for lighting applications. White-emitting organic electroluminescent devices based on low-molecular-weight compounds generally have at least two emission layers. They frequently have at least three emission layers which exhibit blue, green and red emission. Either fluorescent or phosphorescent emitters are used in the emission layers, where the phosphorescent emitters exhibit significant advantages owing to the higher achievable efficiency. The general structure of a white-emitting OLED of this type having at least one phosphorescent layer is described, for example, in WO 05/011013.

However, there is still a need for improvement in white-emitting OLEDs. This applies, in particular, to electroluminescent devices which are doped with a phosphorescent emitter. Thus, it has been found that it is difficult to set the desired colour location. This applies, in particular, in the case of white-emitting OLEDs having a plurality of emission layers. The colour location here can only be set by trial and error. The colour location can be set in a certain, narrowly delimited range by variation of the layer thicknesses of the emission or transport layers or variation of the emitter concentrations in the emitter layers. Otherwise, it must be attempted to achieve the desired colour location range by choosing other materials, in particular other emitter materials. By contrast, it is particularly difficult, on use of the same materials and the same basic layer structure, to cover a broad region of the black-body curve in colour space, for example from illuminant A (CIE 1931 0.45/0.41) to illuminant D65 (CIE 1931 0.31/0.33), only by varying the layer thickness and concentration. However, this is desirable, for example for lighting applications, in order to achieve white having various colour temperatures.

The technical object on which the present invention is based therefore consists in providing a white-emitting organic electroluminescent device in which the colour location can be set more simply. A further object consists in providing a method for improving the adjustability of the colour location of a white-emitting organic electroluminescent device.

In accordance with the prior art, electron-conducting materials, inter alia ketones (for example in accordance with WO 04/093207 or in accordance with the unpublished application DE 102008033943.1), are used as matrix materials for phosphorescent emitters. Low operating voltages and long lifetimes are achieved, in particular, using ketones, which makes this class of compounds a very interesting matrix material. However, there is still a need for improvement with respect to the adjustability of the colour location on use of these matrix materials and in the case of other matrix materials if these are used in white-emitting OLEDs.

Surprisingly, it has been found that the colour location of a white-emitting organic electroluminescent device which has at least three emitting layers, where at least the central of the three layers comprises at least one phosphorescent emitter, can be set particularly well and simply if the central layer which comprises the phosphorescent emitter comprises at least two different matrix materials, one of which has hole-conducting properties and the other has electron-conducting properties.

Particularly good success is achieved if the electron-conducting matrix material is an aromatic ketone.

These organic electroluminescent devices additionally exhibit a very good lifetime and very good colour stability with the lifetime.

The prior art discloses organic electroluminescent devices which comprise a phosphorescent emitter doped into a mixture of two matrix materials.

US 2007/0252516 discloses phosphorescent organic electroluminescent devices which comprise a mixture of a hole-conducting matrix material and an electron-conducting matrix material. Improved efficiency is disclosed for these OLEDs.

US 2007/0099026 discloses white-emitting organic electroluminescent devices in which the green- or red-emitting layer comprises a phosphorescent emitter and a mixture of a hole-conducting matrix material and an electron-conducting matrix material. Hole-conducting materials mentioned are, inter alia, triarylamine and carbazole derivatives. Electron-conducting materials mentioned are, inter alia, aluminium and zinc compounds, oxadiazole compounds and triazine or triazole compounds. Good efficiencies and a long lifetime are disclosed for these OLEDs. There is not mention of this device structure affecting the adjustability of the colour location of the OLED.

The invention thus relates to an organic electroluminescent device comprising an anode, a cathode and at least three emitting layers A, B and C following one another in this sequence, characterised in that emitting layer B, which is located between layers A and C, comprises at least one phosphorescent compound, furthermore at least one hole-conducting material and at least one aromatic ketone.

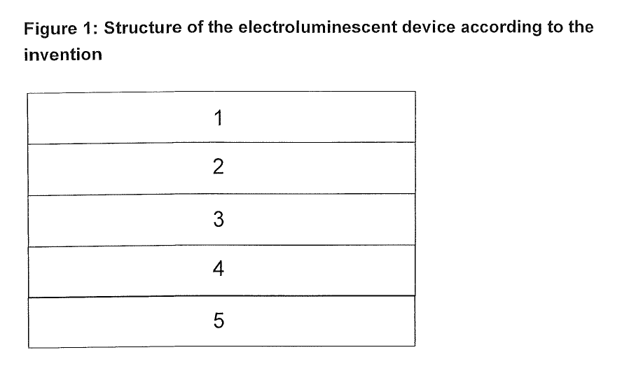

The general device structure is shown diagrammatically in FIG. 1. Layer 1 here stands for the anode, layer 2 for emitting layer A, layer 3 for emitting layer B, layer 4 for emitting layer C and layer 5 for the cathode.

It is also possible for the organic electroluminescent device to have more than three emitting layers.

The emitting layers here may be directly adjacent to one another or separated from one another by interlayers.

In a preferred embodiment of the invention, emission layers A, B and C have different emission colours, where the emission maxima preferably differ from one another by at least 20 nm in each case. A particularly preferred embodiment of the invention relates to a white-emitting organic electroluminescent device. This is characterised in that it emits light having CIE colour coordinates in the range from 0.28/0.29 to 0.45/0.41.

For the purposes of this application, an aromatic ketone is taken to mean a carbonyl group to which two aromatic or heteroaromatic groups or aromatic or heteroaromatic ring systems are bonded directly.

In a preferred embodiment of the invention, the aromatic ketone is a compound of the following formula (1):

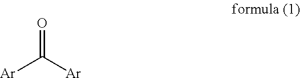

where the following applies to the symbols used:
Ar is on each occurrence, identically or differently, an aromatic or heteroaromatic ring system having 5 to 80 aromatic ring atoms, preferably up to 60 aromatic ring atoms, which may in each case be substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a branched or cyclic alkyl, alkoxy or thioalkoxy group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or an aralkyl or heteroaralkyl group having 5 to 60 aromatic ring atoms, which may be substituted by one or more radicals R², or a combination of these systems; two or more adjacent substituents R¹ here may also form a mono- or polycyclic, aliphatic or aromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D, CN or an aliphatic, aromatic and/or heteroaromatic organic radical having 1 to 20 C atoms, in which, in addition, H atoms may be replaced by F, preferably a hydrocarbon radical; two or more adjacent substituents R² here may also form a mono- or polycyclic, aliphatic or aromatic ring system with one another.

The organic electroluminescent device according to the invention comprises, as described above, an anode, a cathode and at least three emitting layers A, B and C, which are arranged between the anode and the cathode. Emitting layer B comprises at least one phosphorescent compound and furthermore at least one hole-conducting compound and at least one aromatic ketone. The organic electroluminescent device does not necessarily have to comprise only layers built up from organic or organometallic materials. Thus, it is also possible for the anode, cathode and/or one or more layers to comprise inorganic materials or to be built up entirely from inorganic materials.

For the purposes of this invention, a phosphorescent compound is a compound which exhibits luminescence from an excited state having relatively high spin multiplicity, i.e. a spin state >1, in particular from an excited triplet state, at room temperature. For the purposes of this invention, all luminescent transition-metal complexes, in particular all luminescent iridium and platinum compounds, are to be regarded as phosphorescent compounds.

For the purposes of this invention, an aryl group contains at least 6 C atoms; for the purposes of this invention, a heteroaryl group contains at least 2 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, pyrene, quinoline, isoquinoline, etc.

For the purposes of this invention, an aromatic ring system contains at least 6 C atoms in the ring system. For the purposes of this invention, a heteroaromatic ring system contains at least 2 C atoms and at least one heteroatom in the ring system, with the proviso that the sum of C atoms and heteroatoms is at least 5. The heteroatoms are preferably selected from N, O and/or S. For the purposes of this invention, an aromatic or heteroaromatic ring system is intended to be taken to mean a system which does not necessarily contain only aryl or heteroaryl groups, but instead in which a plurality of aryl or heteroaryl groups may also be interrupted by a short non-aromatic unit (preferably less than 10% of the atoms other than H), such as, for example, an sp³-hybridised C, N or O atom or a carbonyl group. Thus, for example, systems such as 9,9′-spirobifluorene, 9,9-diarylfluorene, triarylamine, diaryl ether, stilbene, benzophenone, etc., are also intended to be taken to mean aromatic ring systems for the purposes of this invention. Likewise, an aromatic or heteroaromatic ring system is taken to mean systems in which a plurality of aryl or heteroaryl groups are linked to one another by single bonds, for example biphenyl, terphenyl or bipyridine.

For the purposes of the present invention, a C₁- to C₄₀-alkyl group, in which, in addition, individual H atoms or CH₂ groups may be substituted by the above-mentioned groups, is particularly preferably taken to mean the radicals methyl, ethyl, n-propyl, i-propyl, n-butyl, i-butyl, s-butyl, t-butyl, 2-methylbutyl, n-pentyl, s-pentyl, tent-pentyl, 2-pentyl, cyclopentyl, n-hexyl, s-hexyl, tert-hexyl, 2-hexyl, 3-hexyl, cyclohexyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, trifluoromethyl, pentafluoroethyl and 2,2,2-trifluoroethyl. A C₁- to C₄₀-alkenyl group is preferably taken to mean ethenyl, propenyl, butenyl, pentenyl, cyclopentenyl, hexenyl, cyclohexenyl, heptenyl, cycloheptenyl, octenyl or cyclooctenyl. A C₁- to C₄₀-alkynyl group is preferably taken to mean ethynyl, propynyl, butynyl, pentynyl, hexynyl, heptynyl or octynyl. A C₁- to C₄₀-alkoxy group is particularly preferably taken to mean methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system having 5-60 aromatic ring atoms, which may in each case also be substituted by the above-mentioned radicals R and which may be linked via any desired positions on the aromatic or heteroaromatic ring system, is taken to mean, in particular, groups derived from benzene, naphthalene, anthracene, phenanthrene, benzanthracene, benzophenanthrene, pyrene, chrysene, perylene, fluoroanthene, benzofluoranthene, naphthacene, pentacene, benzopyrene, biphenyl, biphenylene, terphenyl, terphenylene, fluorene, benzofluorene, dibenzofluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The compounds of the formula (1) preferably have a glass-transition temperature T_{G} of greater than 70° C., particularly preferably greater than 90° C., very particularly preferably greater than 110° C.

In a preferred embodiment of the invention, the three emitting layers A, B and C are a red-emitting layer, a green-emitting layer and a blue-emitting layer. A red-emitting layer here is taken to mean a layer whose photoluminescence maximum is in the range from 560 to 750 nm. A green-emitting layer is taken to mean a layer whose photoluminescence maximum is in the range from 490 to 560 nm. A blue-emitting layer is taken to mean a layer whose photoluminescence maximum is in the range from 440 to 490 nm. The photoluminescence maximum is determined by measurement of the photoluminescence spectrum of the layer having a layer thickness of 50 nm.

In a preferred embodiment of the invention, layer A is a red-emitting layer, layer B is a green-emitting layer and layer C is a blue-emitting layer, where layer A is on the anode side and layer C is on the cathode side.

In a further preferred embodiment of the invention, layer A is a blue-emitting layer, layer B is a green-emitting layer and layer C is a red-emitting layer, where layer A is on the anode side and layer C is on the cathode side.

In both of the preferred embodiments of the invention described above, the green-emitting layer B thus comprises the phosphorescent compound, the hole-conducting matrix material and the aromatic ketone.

The proportion of the phosphorescent compound in layer B is preferably 1 to 50% by vol., particularly preferably 3 to 25% by vol., very particularly preferably 5 to 20% by vol.

The ratio between the hole-conducting compound and the ketone can vary. In particular, variation of this ratio enables the colour location of the white-emitting OLED to be set simply and reproducibly. Adjustment of the mixing ratio thus enables the colour location to be set with an accuracy of 0.01 (measured in CIE coordinates). Variation of the mixing ratio of the hole-conducting compound and the ketone thus enables control of the luminous strength of the other emitting layers adjacent to this layer.

The mixing ratio between the hole-conducting compound and the aromatic ketone here is generally from 20:1 to 1:10, preferably from 10:1 to 1:3, particularly preferably from 8:1 to 1:1.

Preferred embodiments of the phosphorescent compound and of the hole-conducting compound and the compound of the formula (1) which are present in accordance with the invention in emitting layer B are shown below.

Suitable phosphorescent compounds are, in particular, compounds which emit light, preferably in the visible region, on suitable excitation and in addition contain at least one atom having an atomic number of greater than 20, preferably greater than 38 and less than 84, particularly preferably greater than 56 and less than 80. Preferred phosphorescence emitters used are compounds which contain copper, molybdenum, tungsten, rhenium, ruthenium, osmium, rhodium, iridium, palladium, platinum, silver, gold or europium, in particular compounds which contain iridium or platinum.

Particularly preferred organic electroluminescent devices comprise, as phosphorescent compound, at least one compound of the formulae (2) to (5):

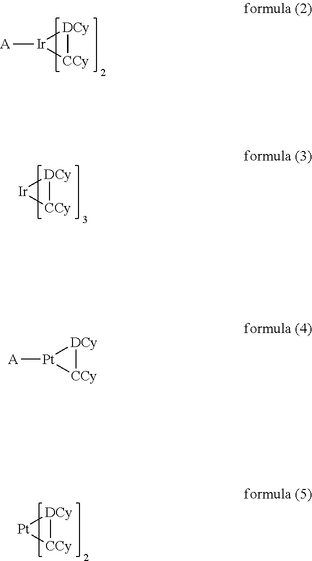

where R¹ has the same meaning as described above for formula (1), and the following applies to the other symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate-chelating ligand, preferably a diketonate ligand or a piccolinate ligand.

A bridge may also be present between the groups DCy and CCy through the formation of ring systems between a plurality of radicals R¹. A bridge may furthermore also be present between two or three ligands CCy-DCy or between one or two ligands CCy-DCy and the ligand A through the formation of ring systems between a plurality of radicals R¹, giving a polydentate or polypodal ligand system.

Examples of the emitters described above are revealed by the applications WO 00/70655, WO 01/41512, WO 02/02714, WO 02/15645, EP 1191613, EP 1191612, EP 1191614, WO 04/081017, WO 05/033244, WO 05/042550, WO 05/113563, WO 06/008069, WO 06/061182, WO 06/081973 and the unpublished application DE 102008027005.9. In general, all phosphorescent complexes as are used in accordance with the prior art for phosphorescent OLEDs and as are known to the person skilled in the art in the area of organic electroluminescence are suitable, and the person skilled in the art will be able to use further phosphorescent compounds without inventive step. In particular, the person skilled in the art knows which phosphorescent complexes emit with which emission colour.

The phosphorescent compound in layer B here is preferably a green-emitting compound, in particular of the formula (3) given above, in particular tris(phenylpyridyl)iridium, which may be substituted by one or more radicals R¹. The phosphorescent compound is very particularly preferably tris(phenylpyridyl)iridium.

Examples of preferred phosphorescent compounds A and B are shown in the following table.

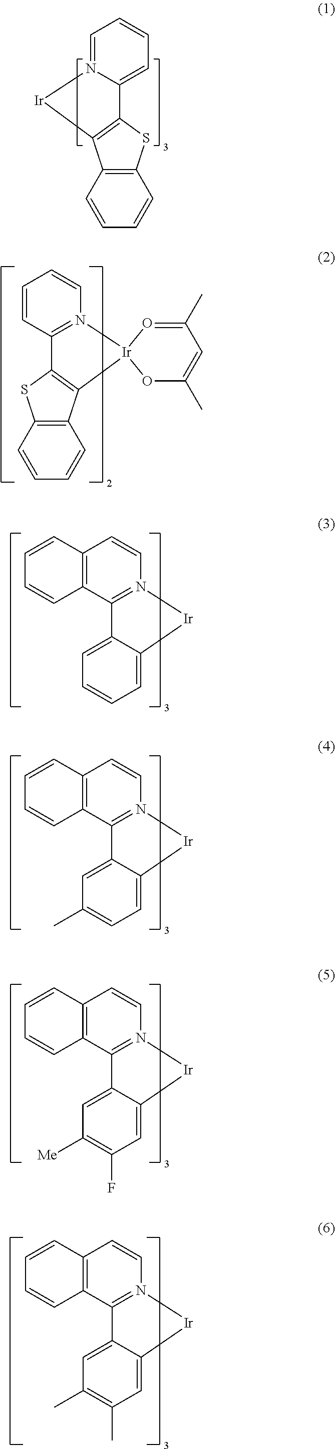

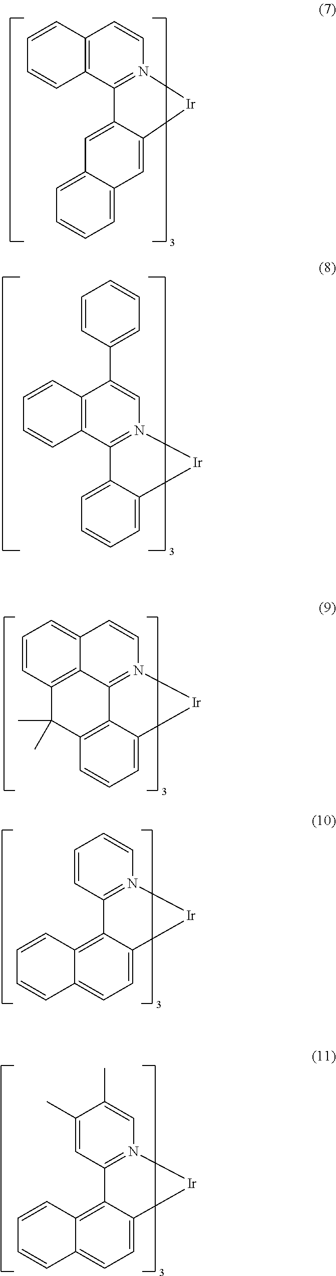

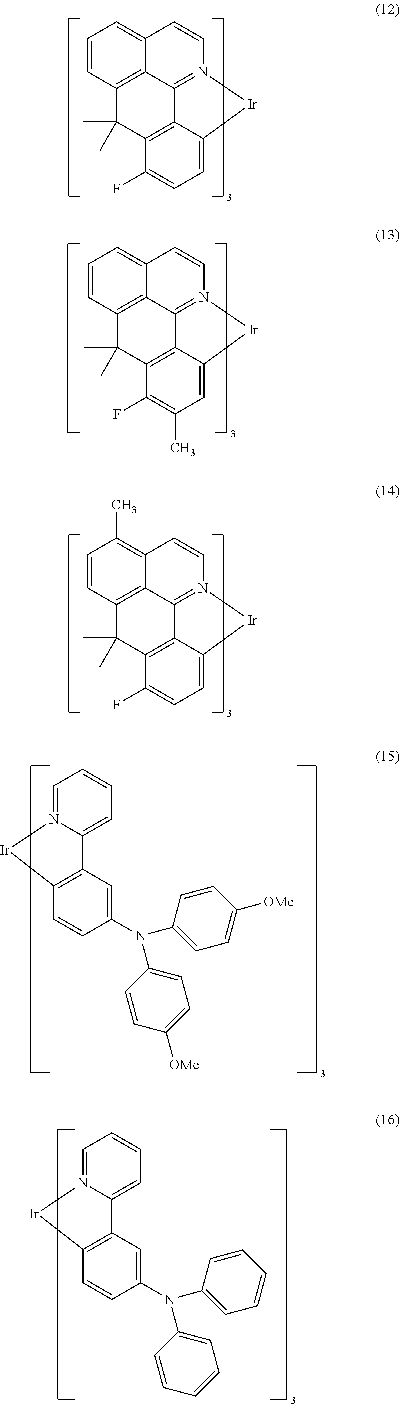

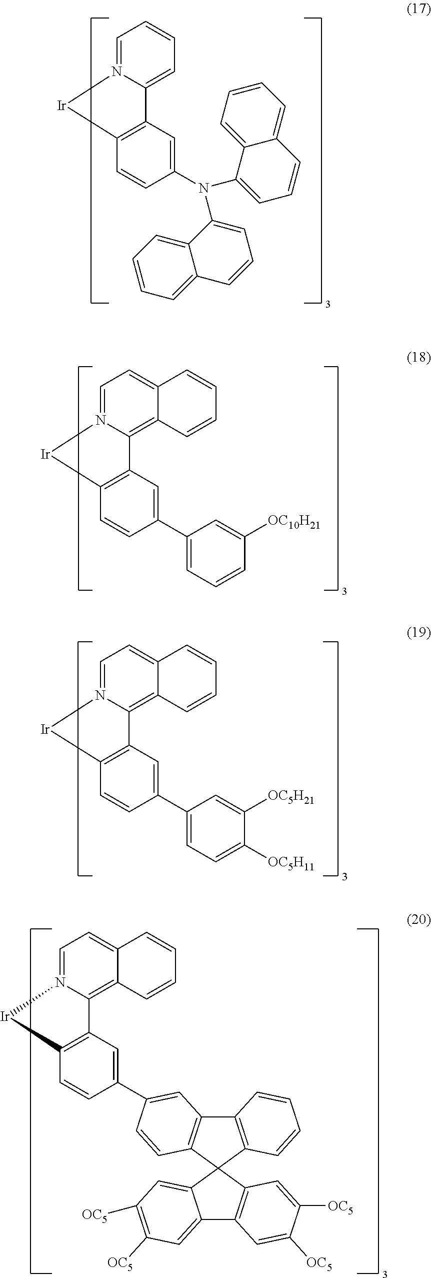

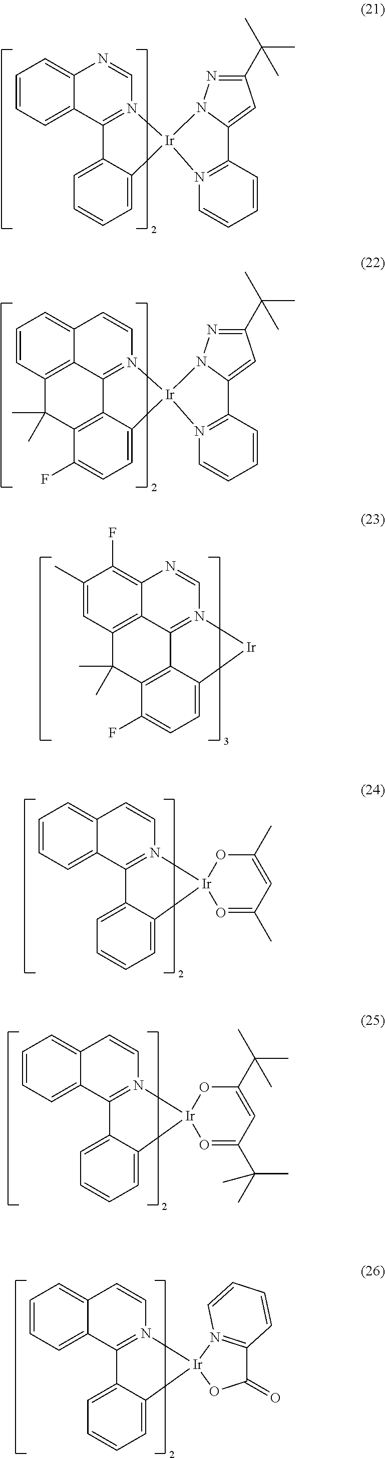

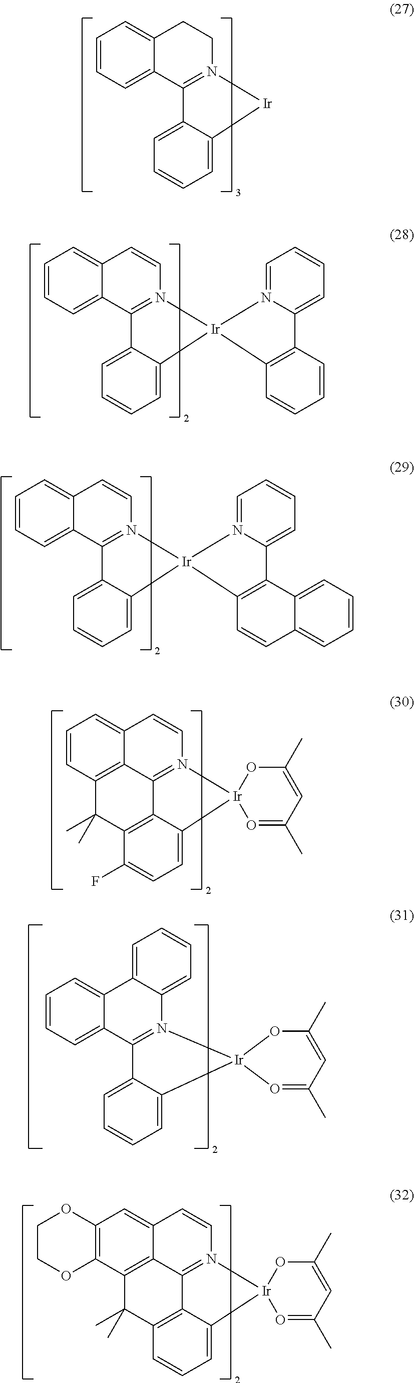

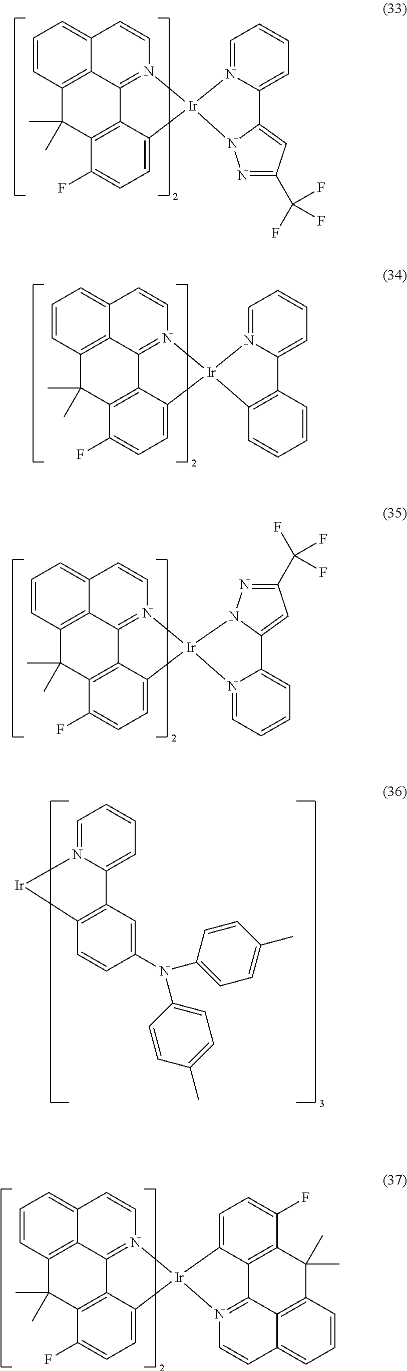

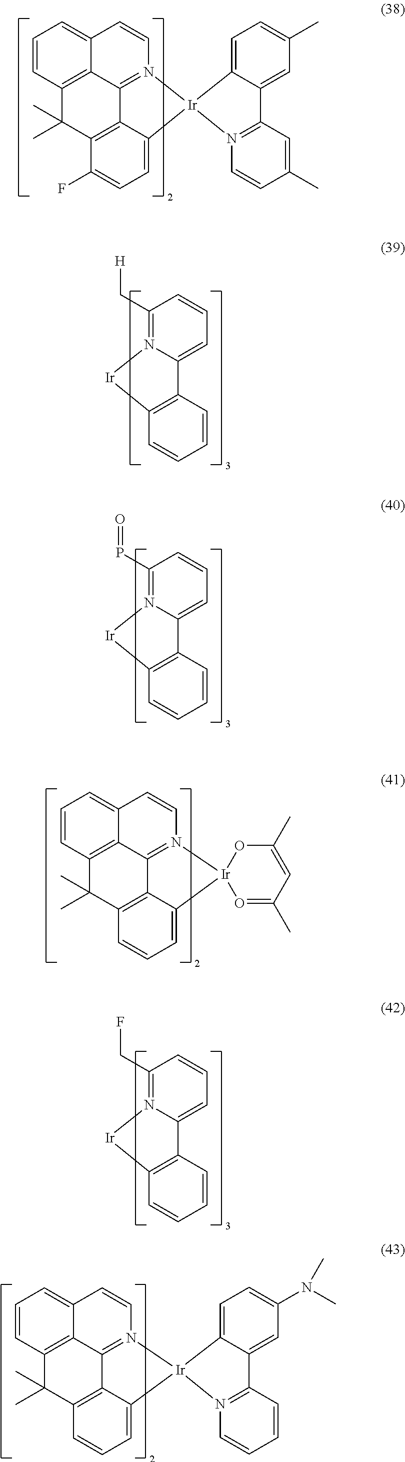

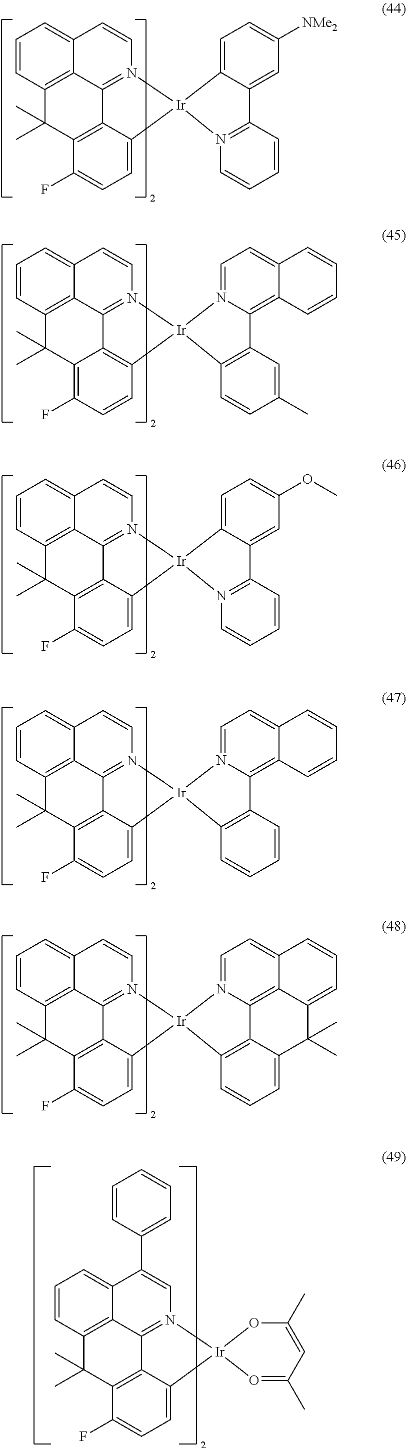

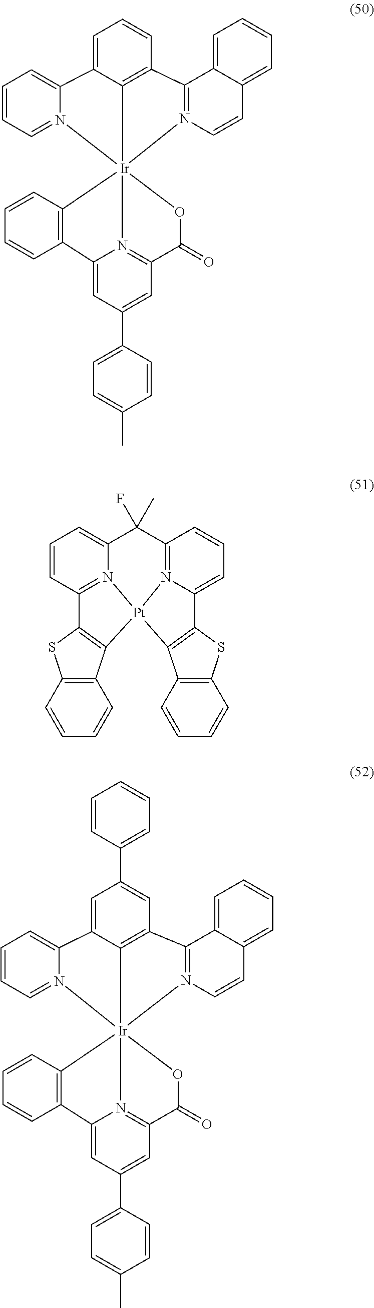

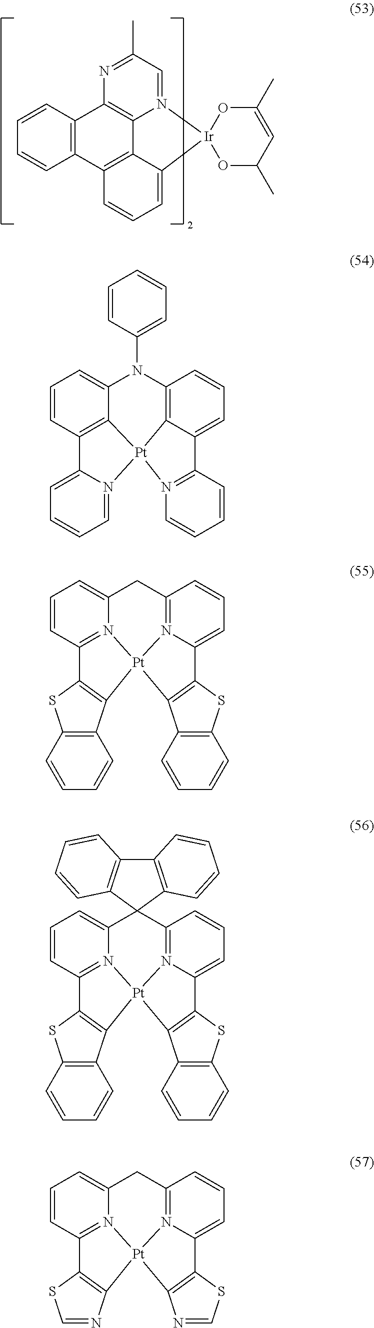

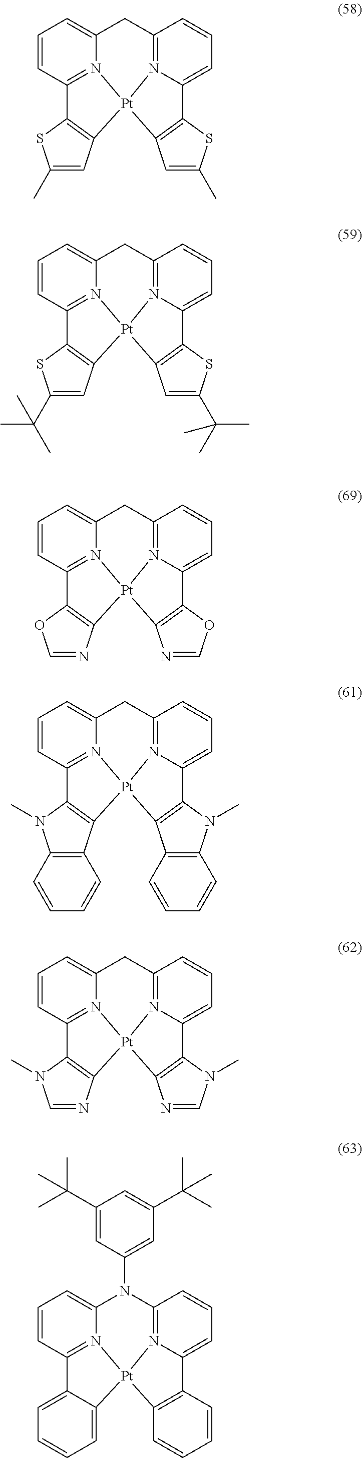

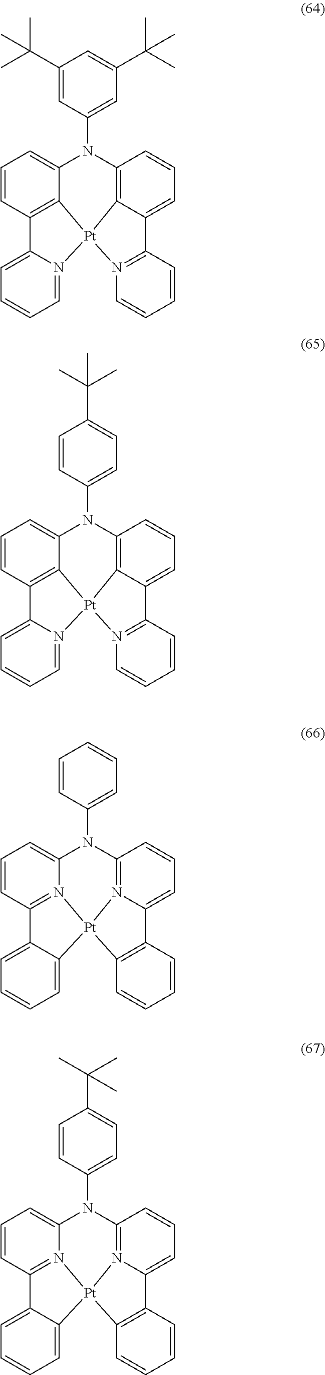

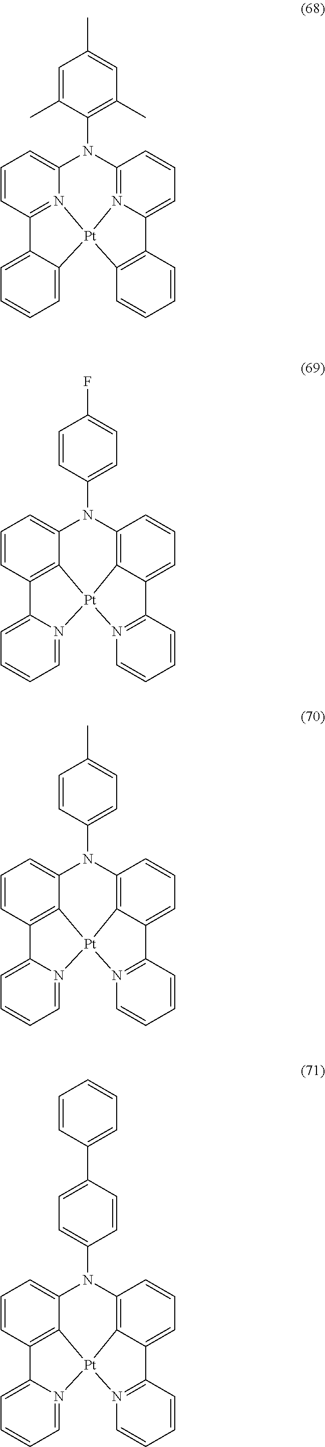

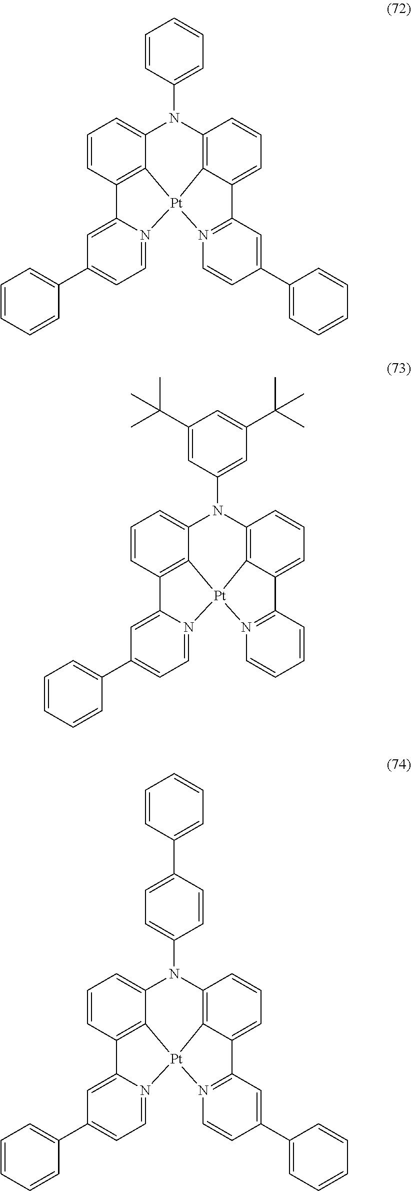

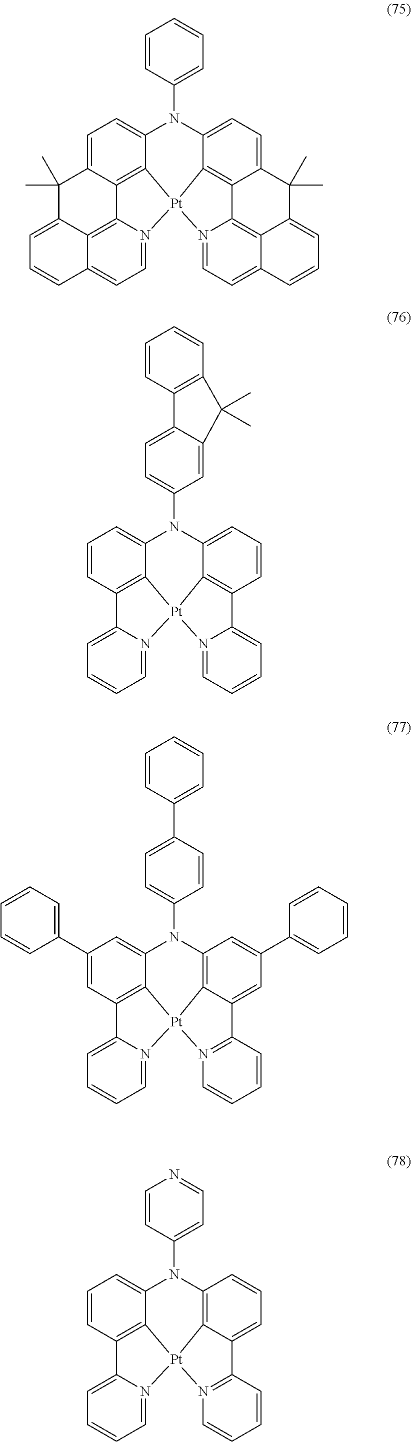

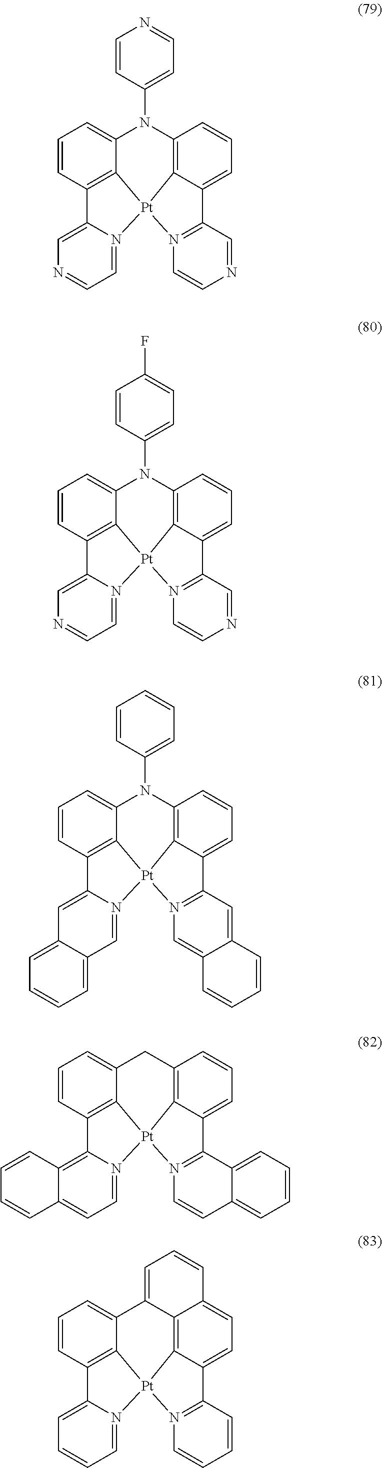

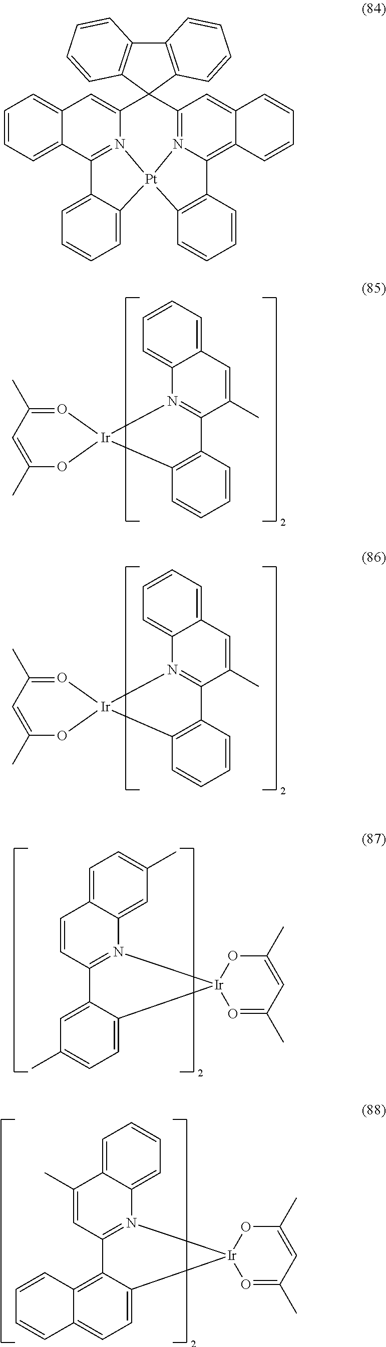

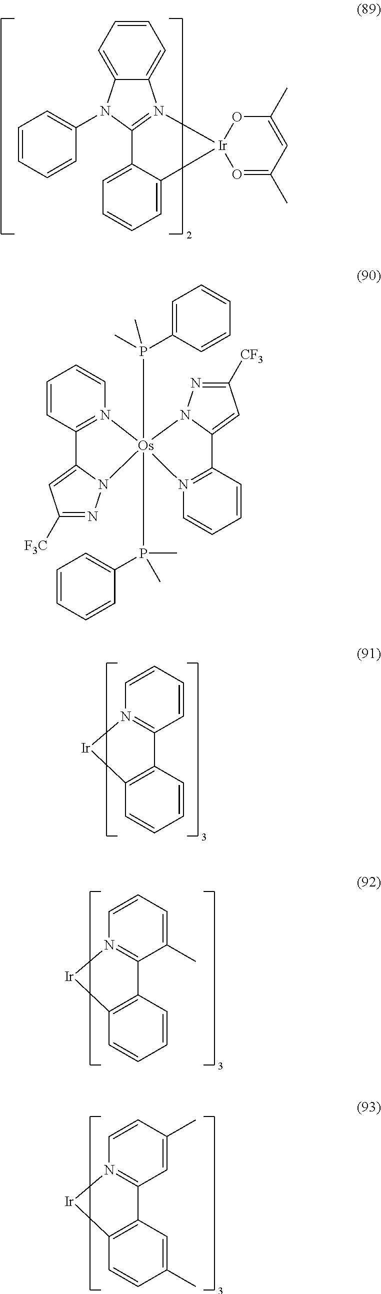

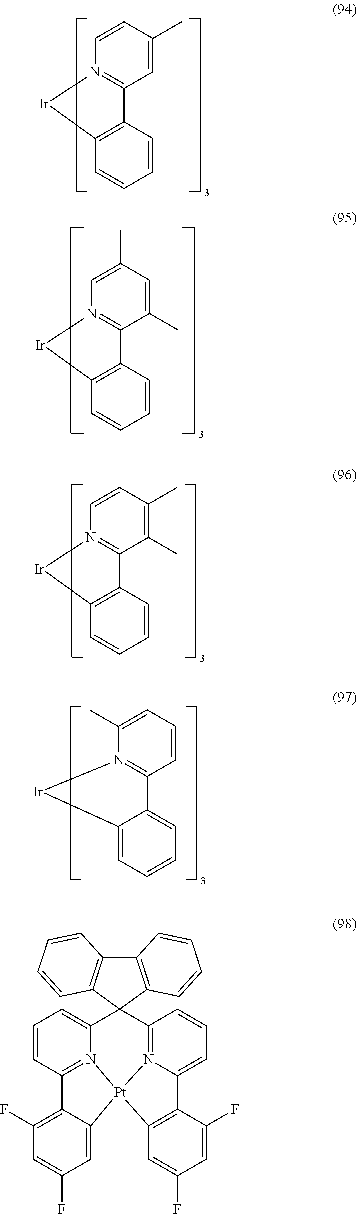

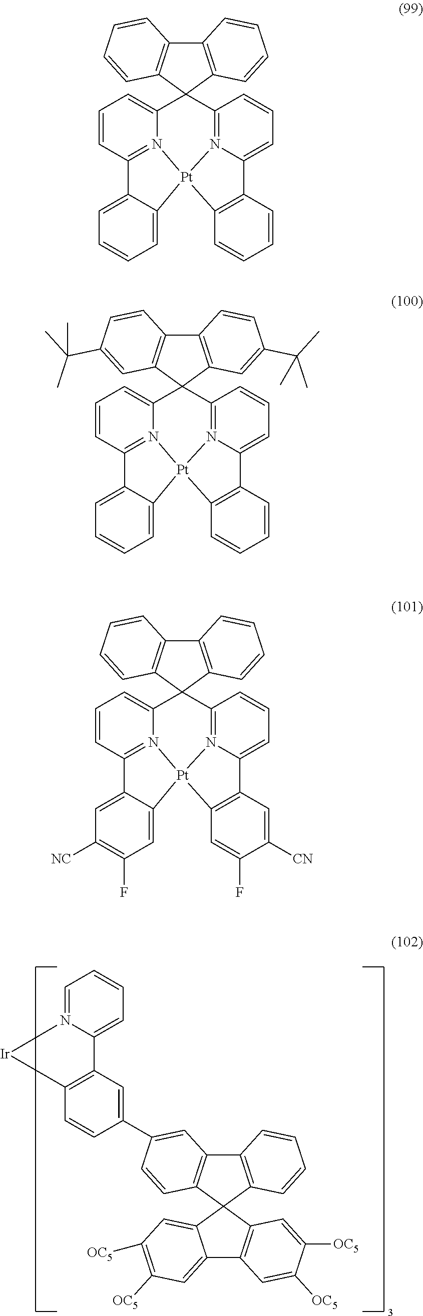

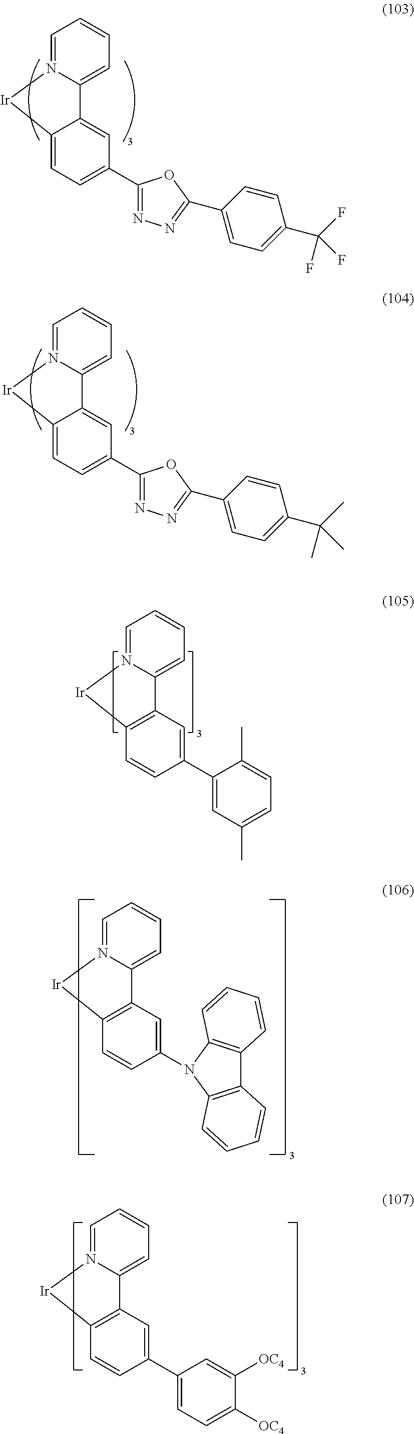

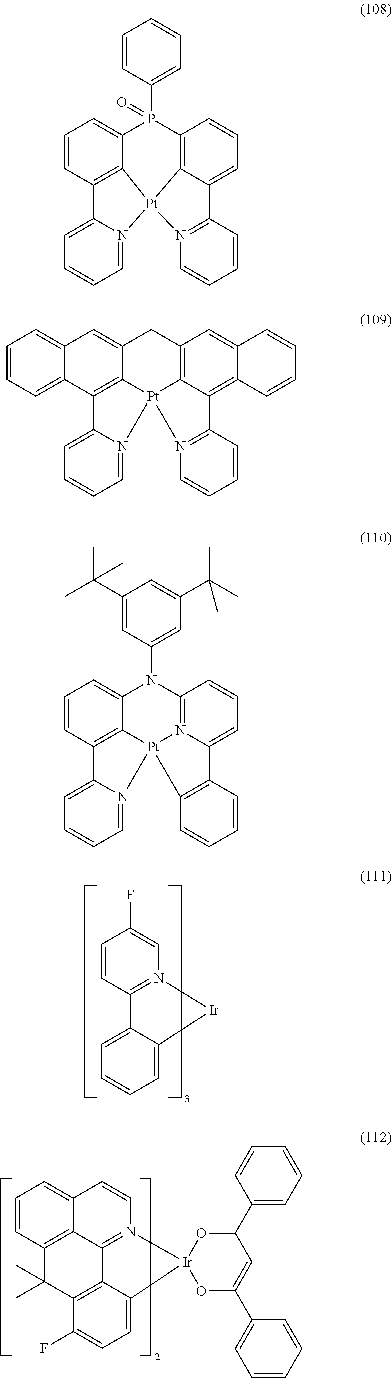

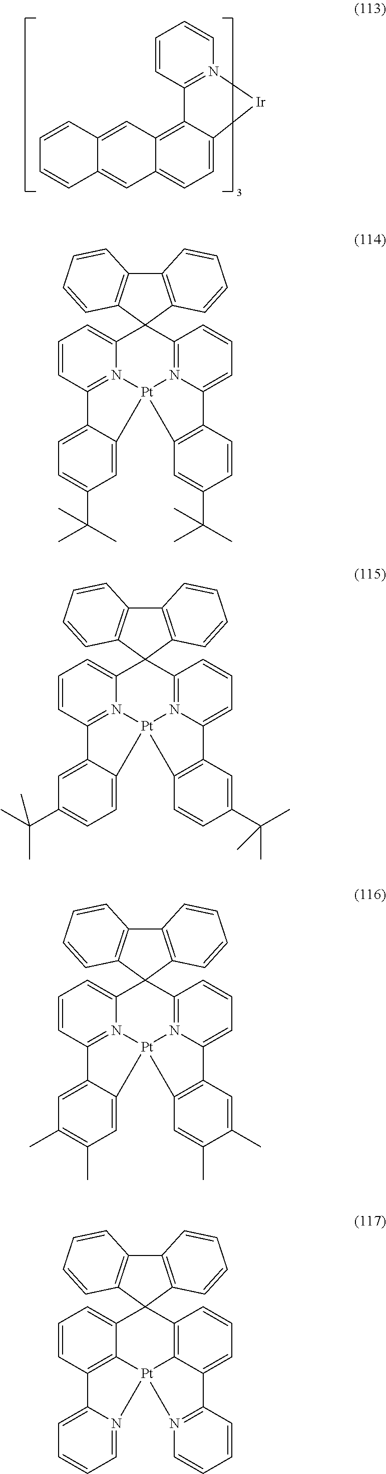

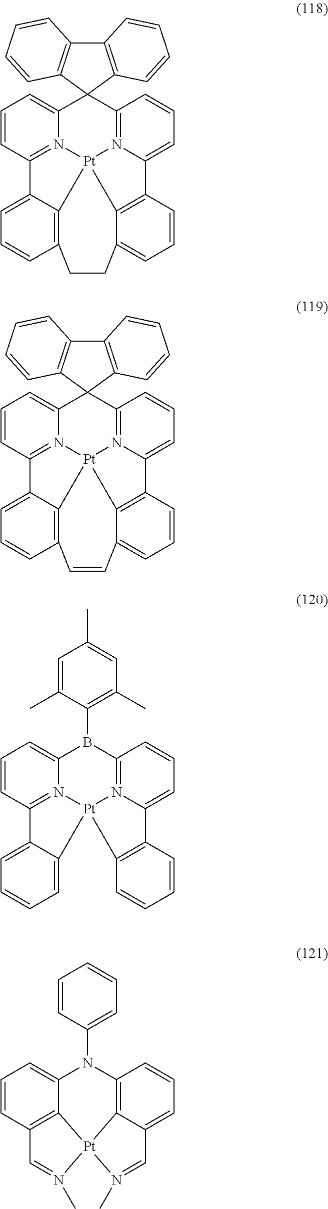

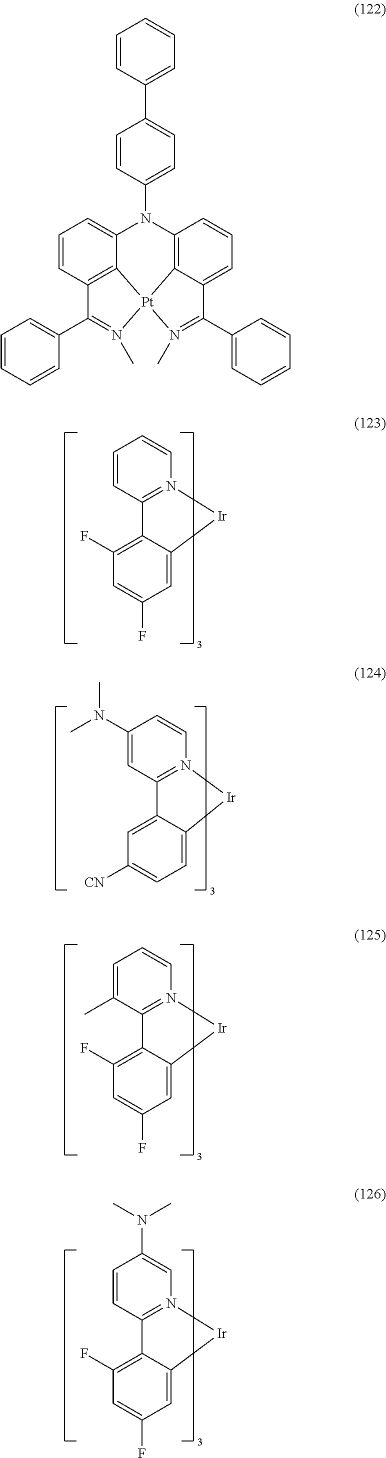

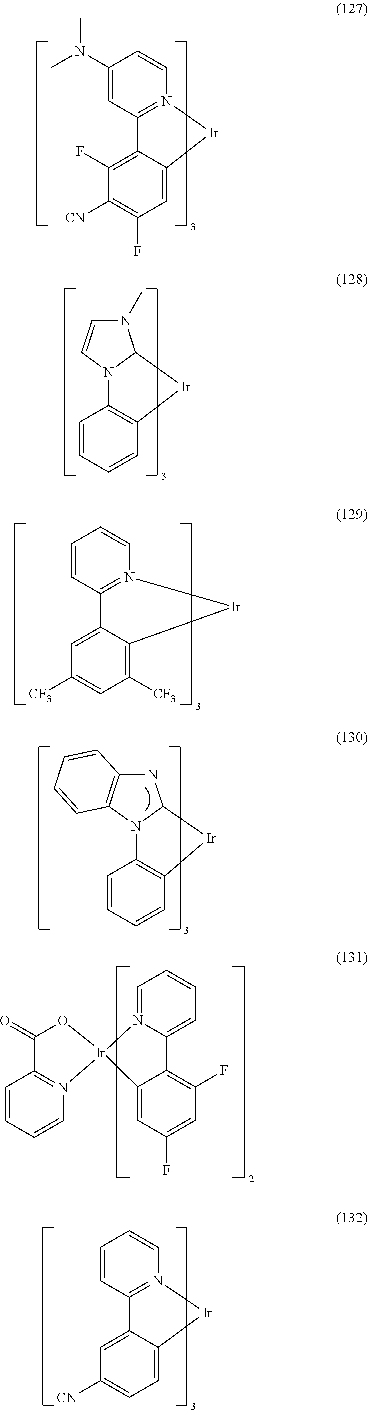

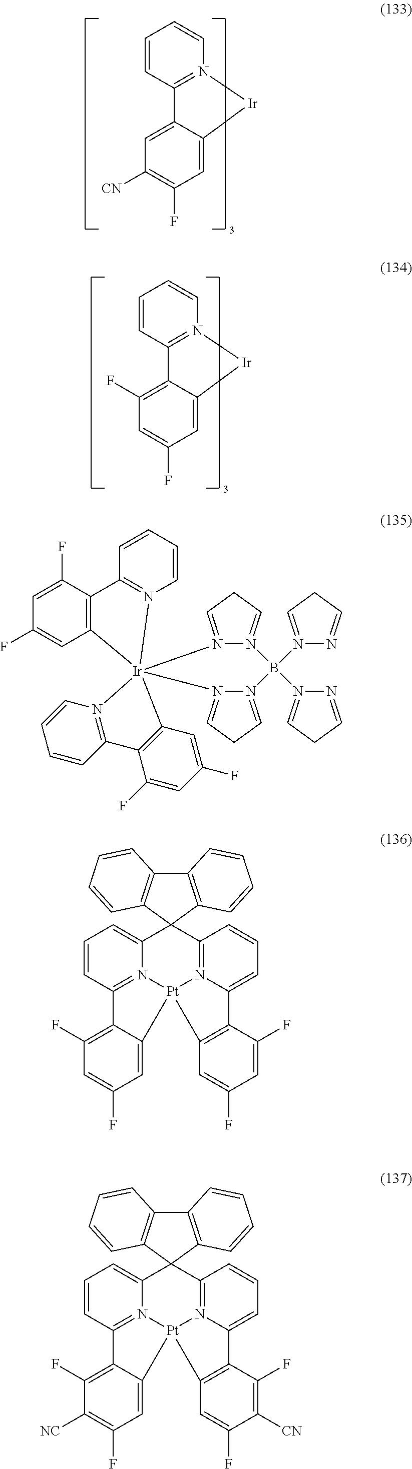

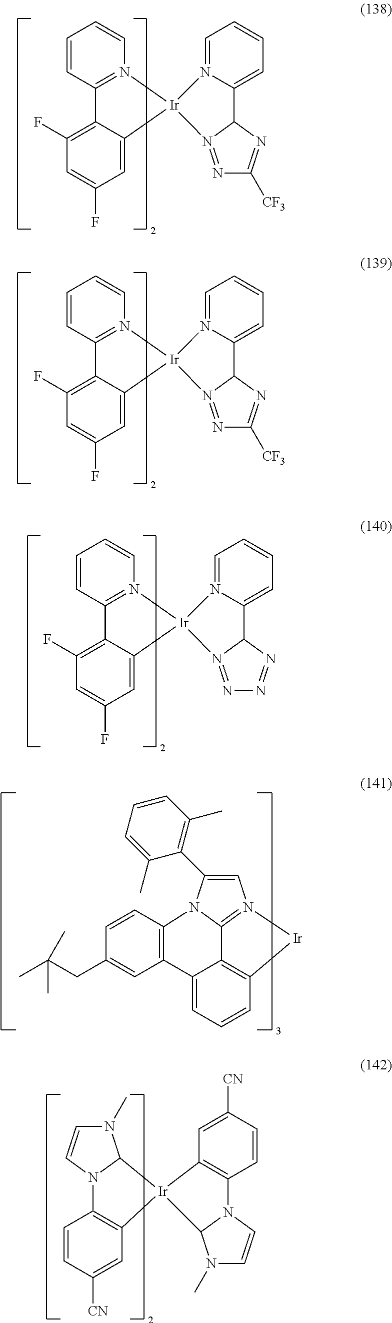

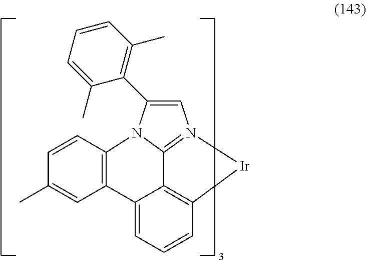

As described above, compounds of the formula (1) are used as matrix material.

Suitable compounds of the formula (1) are, in particular, the ketones disclosed in WO 04/093207 and the unpublished DE 102008033943.1. These are incorporated into the present invention by way of reference.

It is evident from the definition of the compound of the formula (1) that this does not have to contain only one carbonyl group, but instead may also contain a plurality of these groups.

The group Ar in compounds of the formula (1) is preferably an aromatic ring system having 6 to 40 aromatic ring atoms, i.e. it does not contain any heteroaryl groups. As defined above, the aromatic ring system does not necessarily have to contain only aromatic groups, but instead two aryl groups may also be interrupted by a non-aromatic group, for example by a further carbonyl group.

In a further preferred embodiment of the invention, the group Ar contains not more than two condensed rings. It is thus preferably built up only from phenyl and/or naphthyl groups, particularly preferably only from phenyl groups, but does not contain any larger condensed aromatic systems, such as, for example, anthracene.

Preferred groups Ar which are bonded to the carbonyl group are phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthylnaphthyl), 1-, 2- or 3-(4-naphthylphenyl), 2-, 3- or 4-pyridyl, 2-, 4- or 5-pyrimidinyl, 2- or 3-pyrazinyl, 3- or 4-pyridazinyl, 2-(1,3,5-triazin)yl, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

The groups Ar may be substituted by one or more radicals R¹. These radicals R¹ are preferably selected, identically or differently on each occurrence, from the group consisting of H, D, F, C(═O)Ar¹, P(═O)(Ar¹)₂, S(═O)Ar¹, S(═O)₂Ar¹, a straight-chain alkyl group having 1 to 4 C atoms or a branched or cyclic alkyl group having 3 to 5 C atoms, each of which may be substituted by one or more radicals R², where one or more H atoms may be replaced by F, or an aromatic ring system having 6 to 24 aromatic ring atoms, which may be substituted by one or more radicals R², or a combination of these systems; two or more adjacent substituents R¹ here may also form a mono- or polycyclic, aliphatic or aromatic ring system with one another. If the organic electroluminescent device is applied from solution, straight-chain, branched or cyclic alkyl groups having up to 10 C atoms are also preferred as substituents R¹. The radicals R¹ are particularly preferably selected, identically or differently on each occurrence, from the group consisting of H, C(═O)Ar¹ or an aromatic ring system having 6 to 24 aromatic ring atoms, which may be substituted by one or more radicals R², but is preferably unsubstituted.

In another preferred embodiment of the invention, the group Ar¹ is, identically or differently on each occurrence, an aromatic ring system having 6 to 24 aromatic ring atoms, which may be substituted by one or more radicals R². Ar¹ is particularly preferably, identically or differently on each occurrence, an aromatic ring system having 6 to 12 aromatic ring atoms.

Particular preference is given to benzophenone derivatives, each of which is substituted at the 3,5,3′,5′-positions by an aromatic or heteroaromatic ring system having 5 to 30 aromatic ring atoms, which may in turn be substituted by one or more radicals R¹ as defined above. Preference is furthermore given to ketones which are substituted by at least one spirobifluorene group.

Preferred aromatic ketones are therefore the compounds of the following formulae (6) to (9):

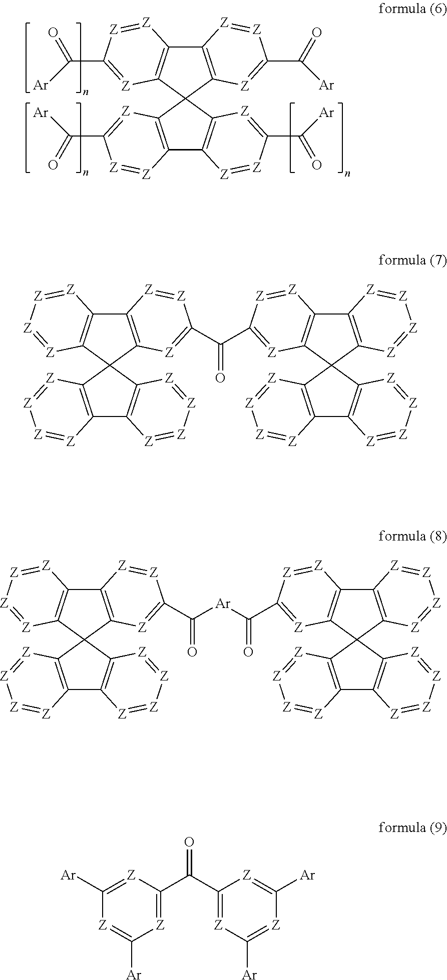

where Ar and R¹ have the same meaning as described above, and furthermore:
Z is, identically or differently on each occurrence, CR¹ or N;
n is, identically or differently on each occurrence, 0 or 1.

Ar in the formulae (6) and (9) given above preferably stands for an aromatic or heteroaromatic ring system having 5 to 30 aromatic ring atoms, which may be substituted by one or more radicals R¹. The above-mentioned groups Ar are particularly preferred.

Examples of suitable compounds of the formula (1) are compounds (1) to (59) depicted below.

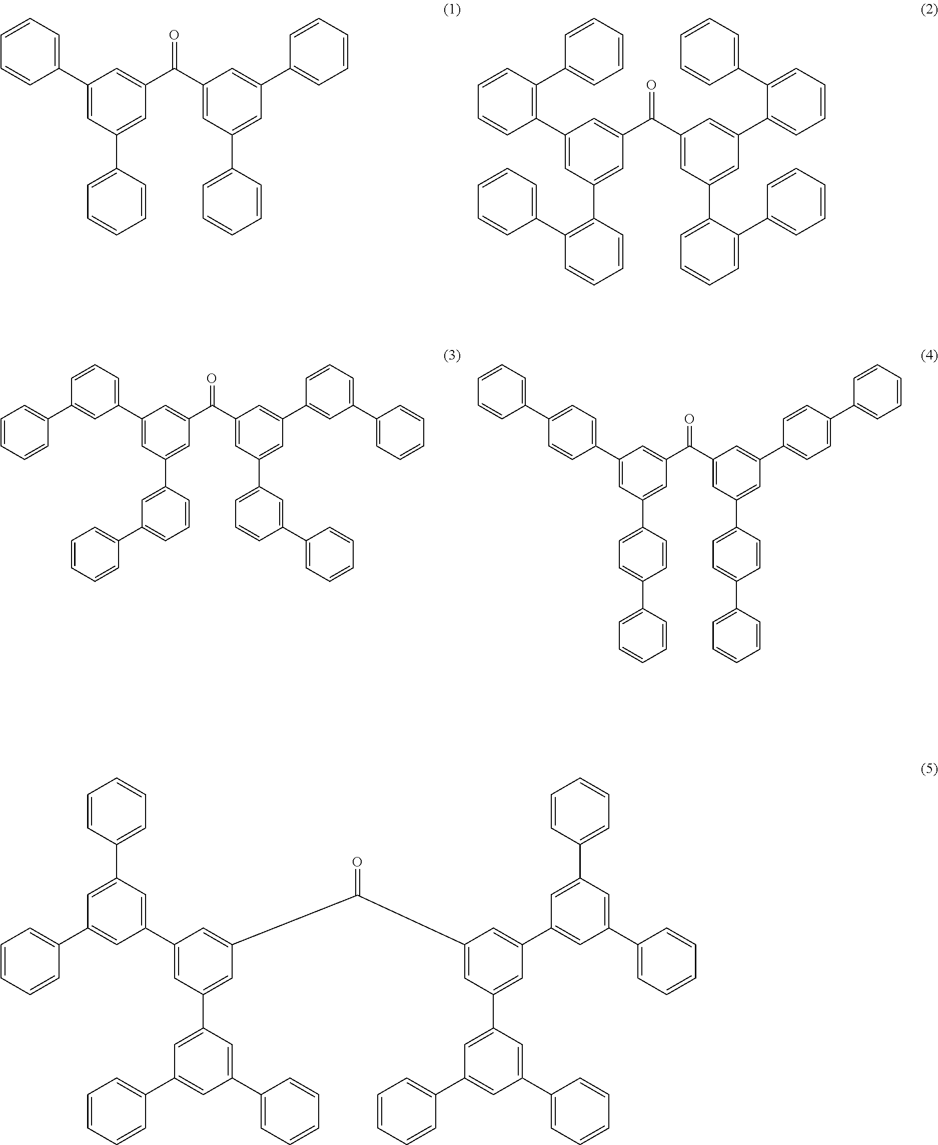

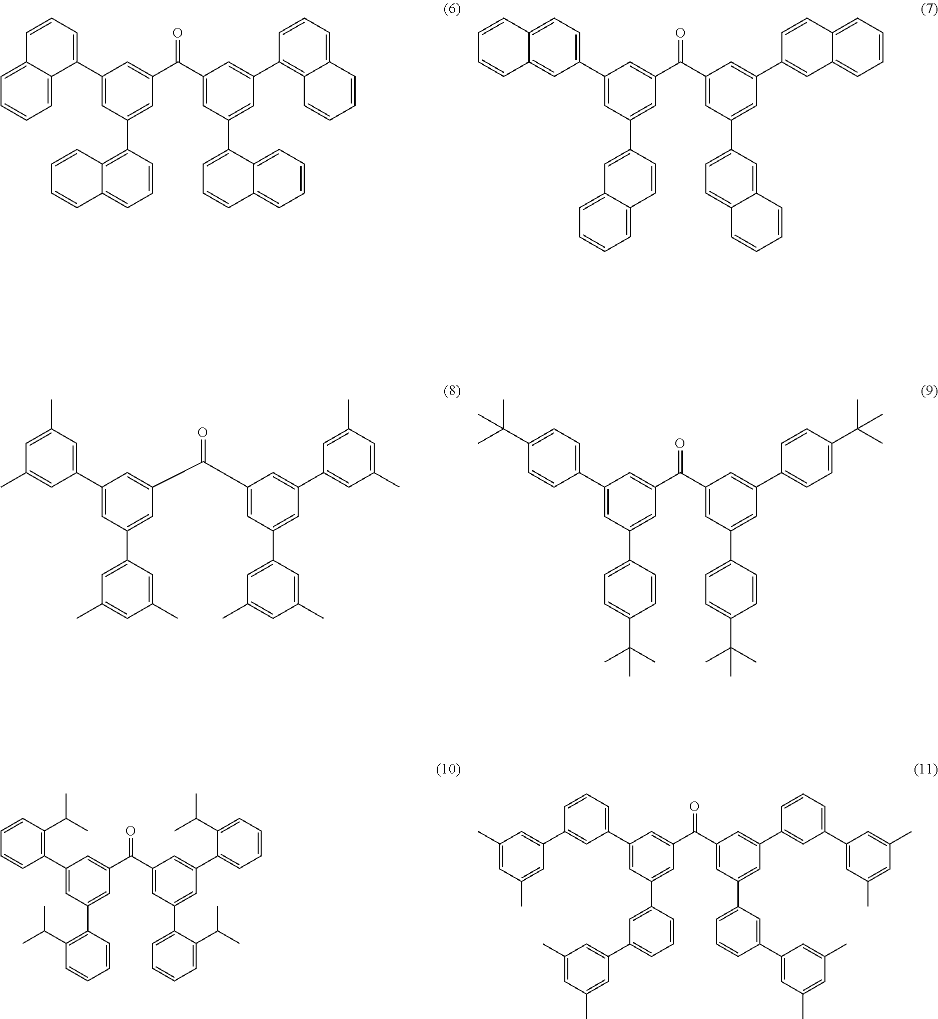

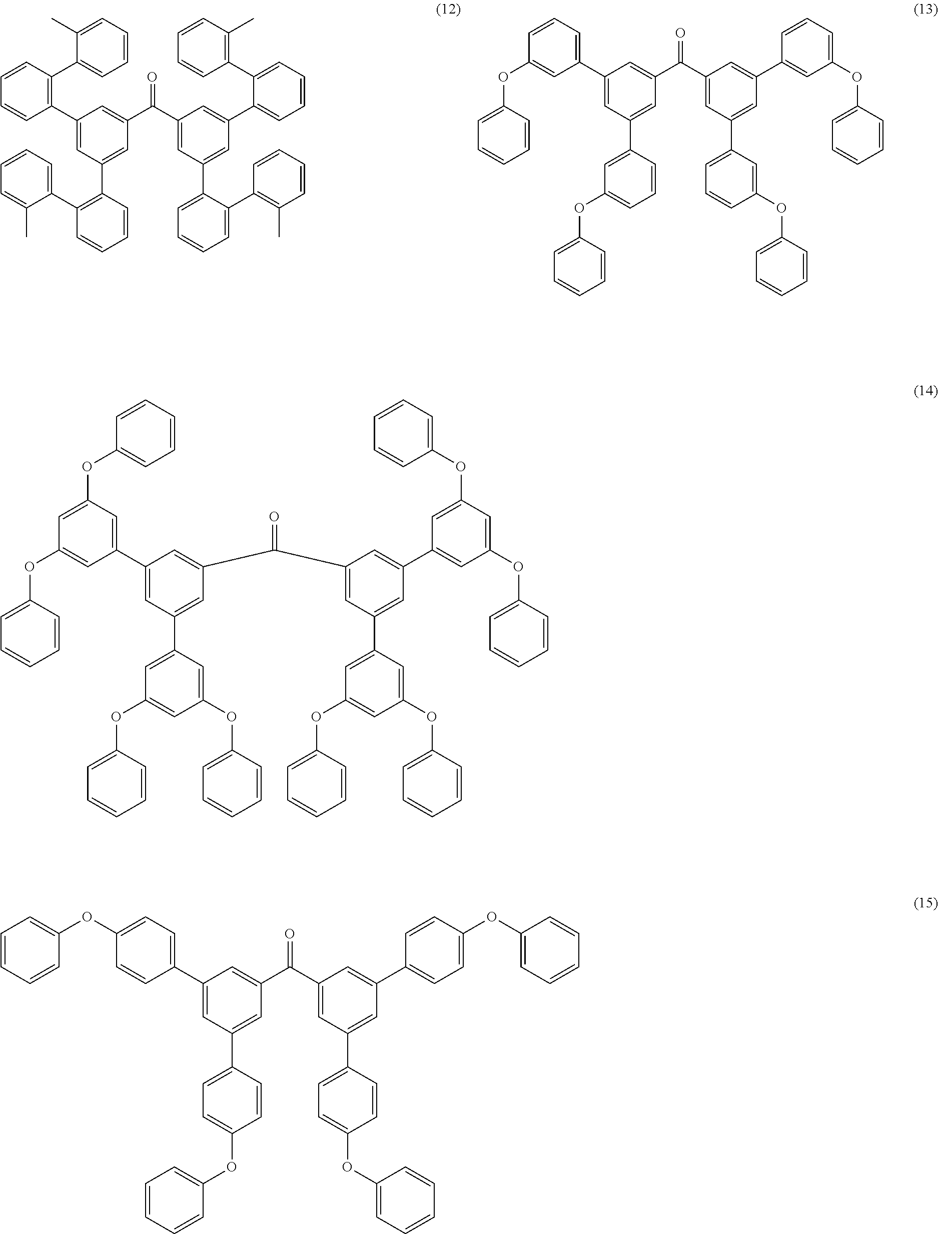

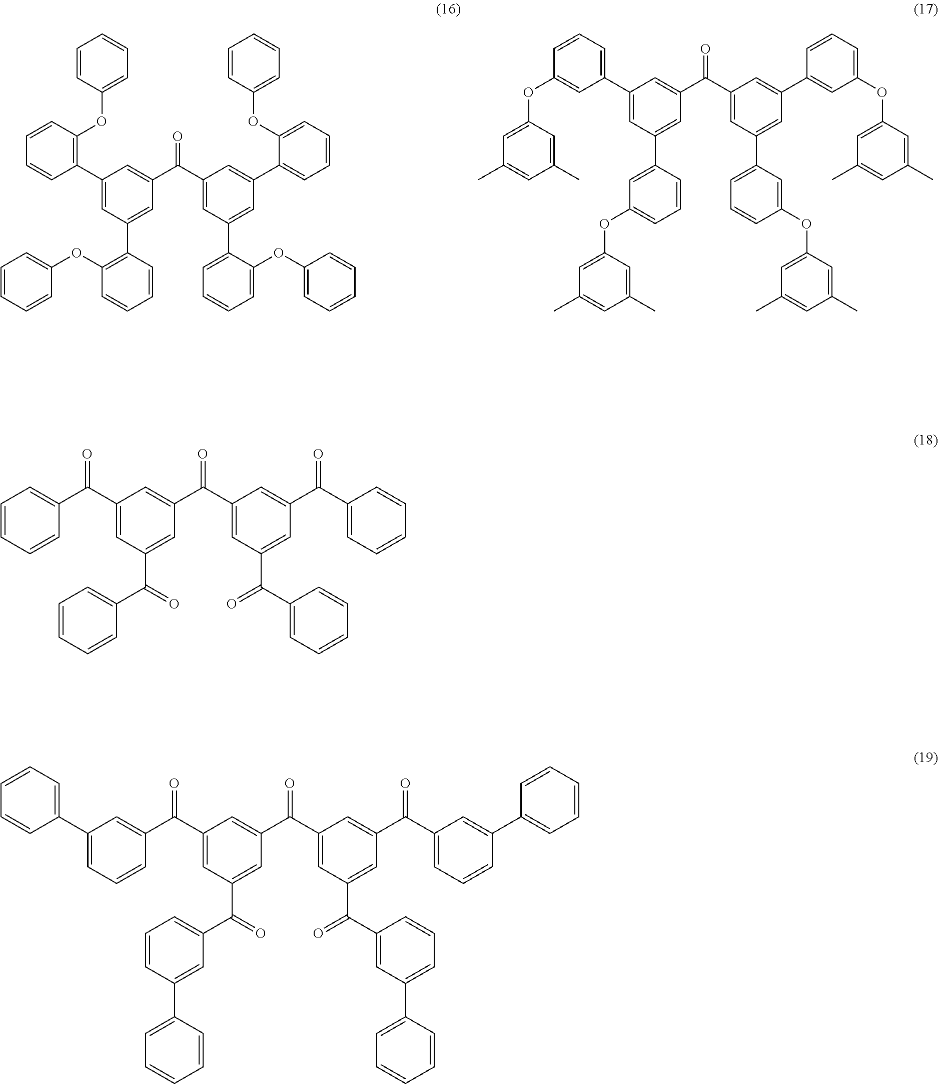

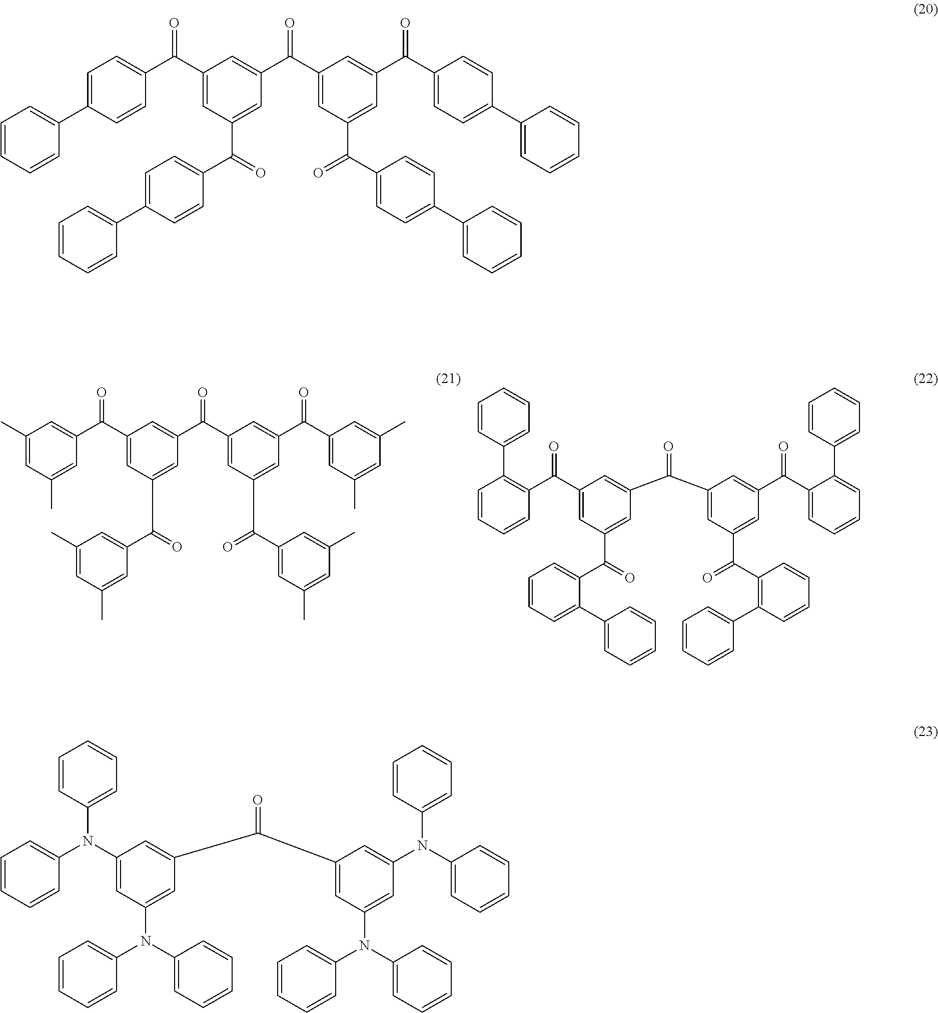

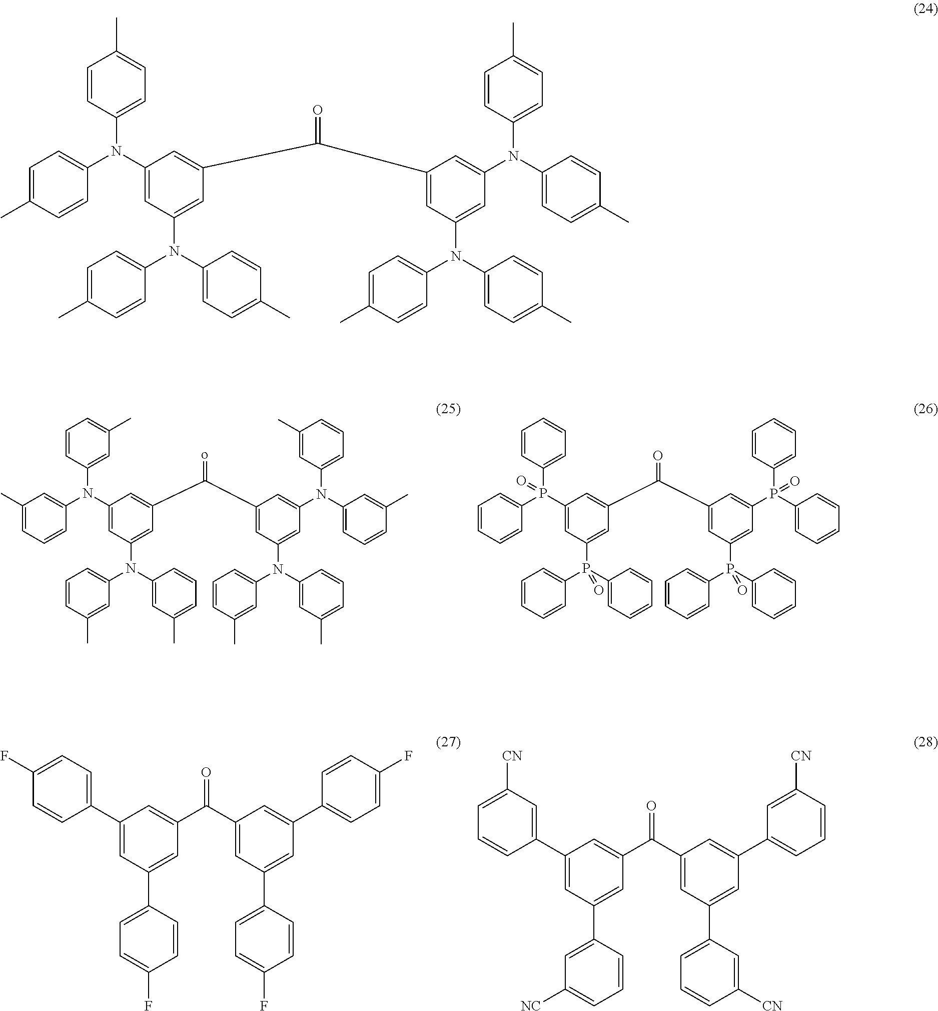

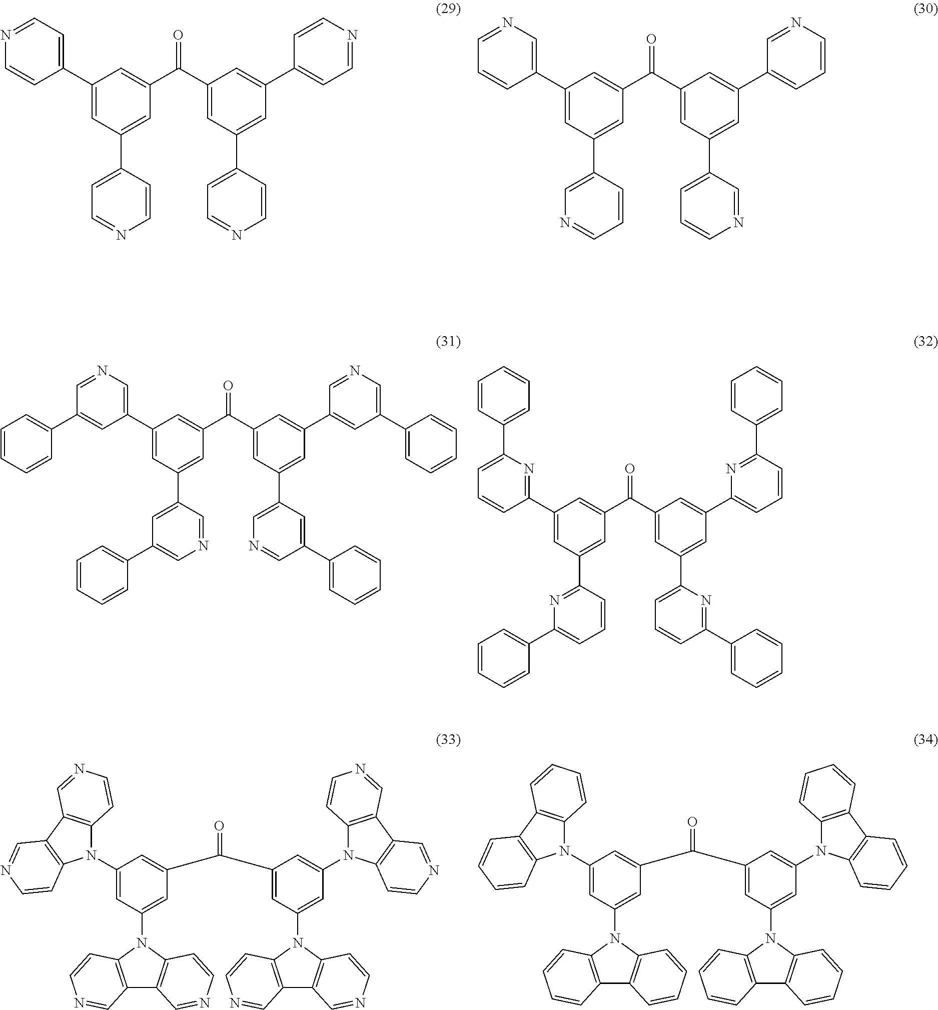

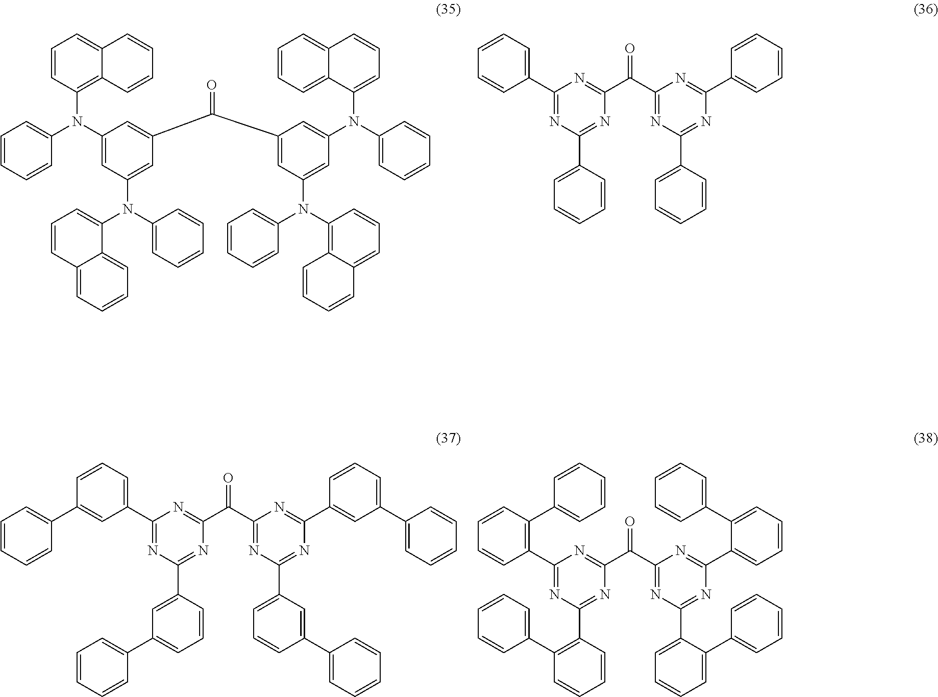

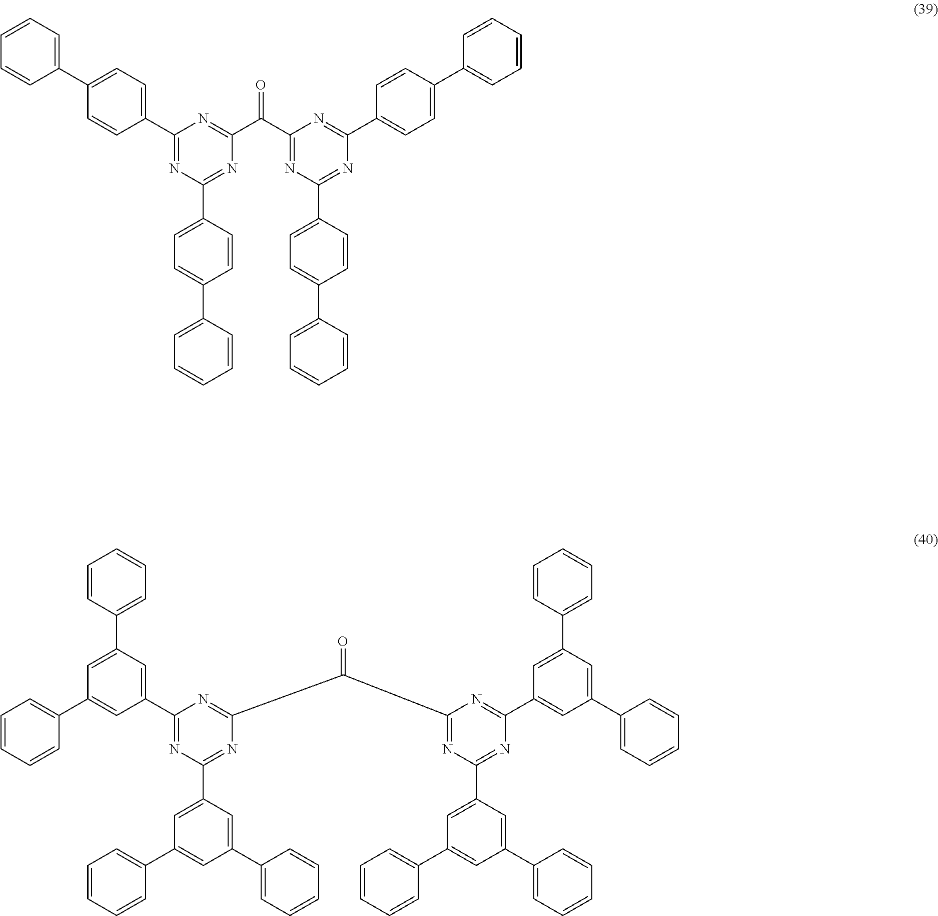

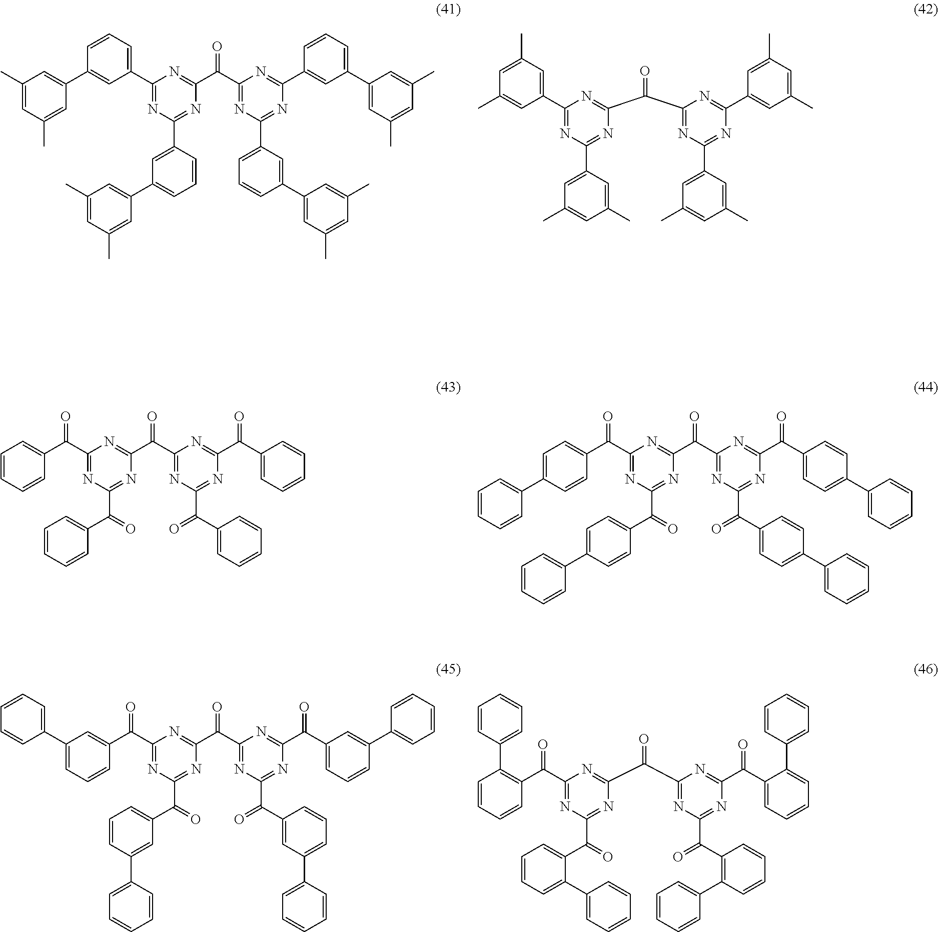

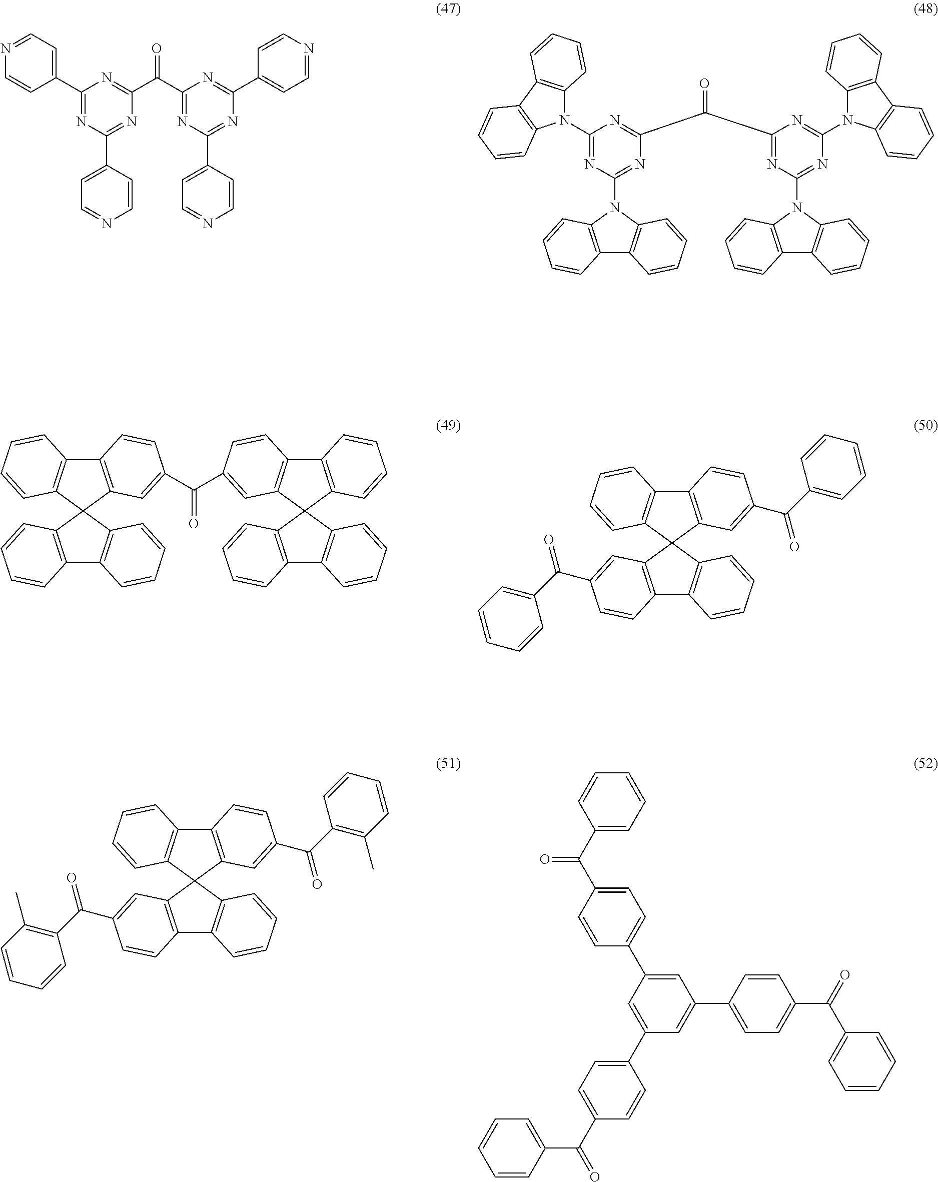

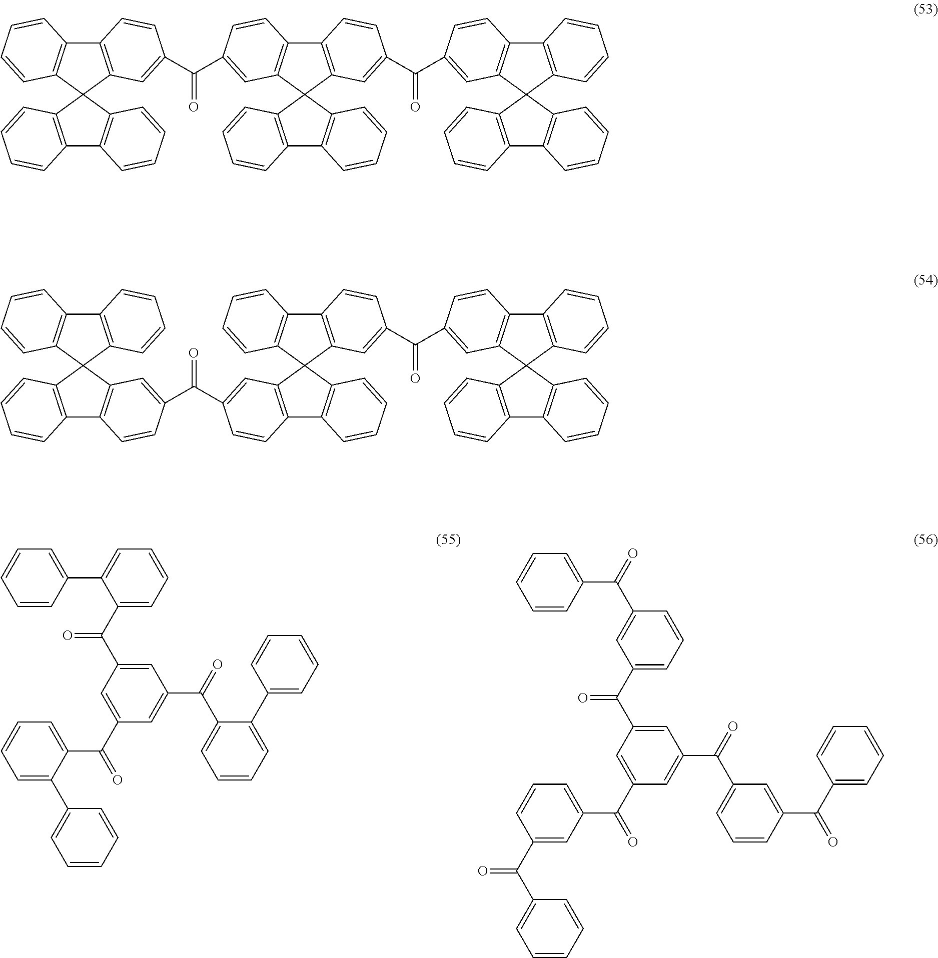

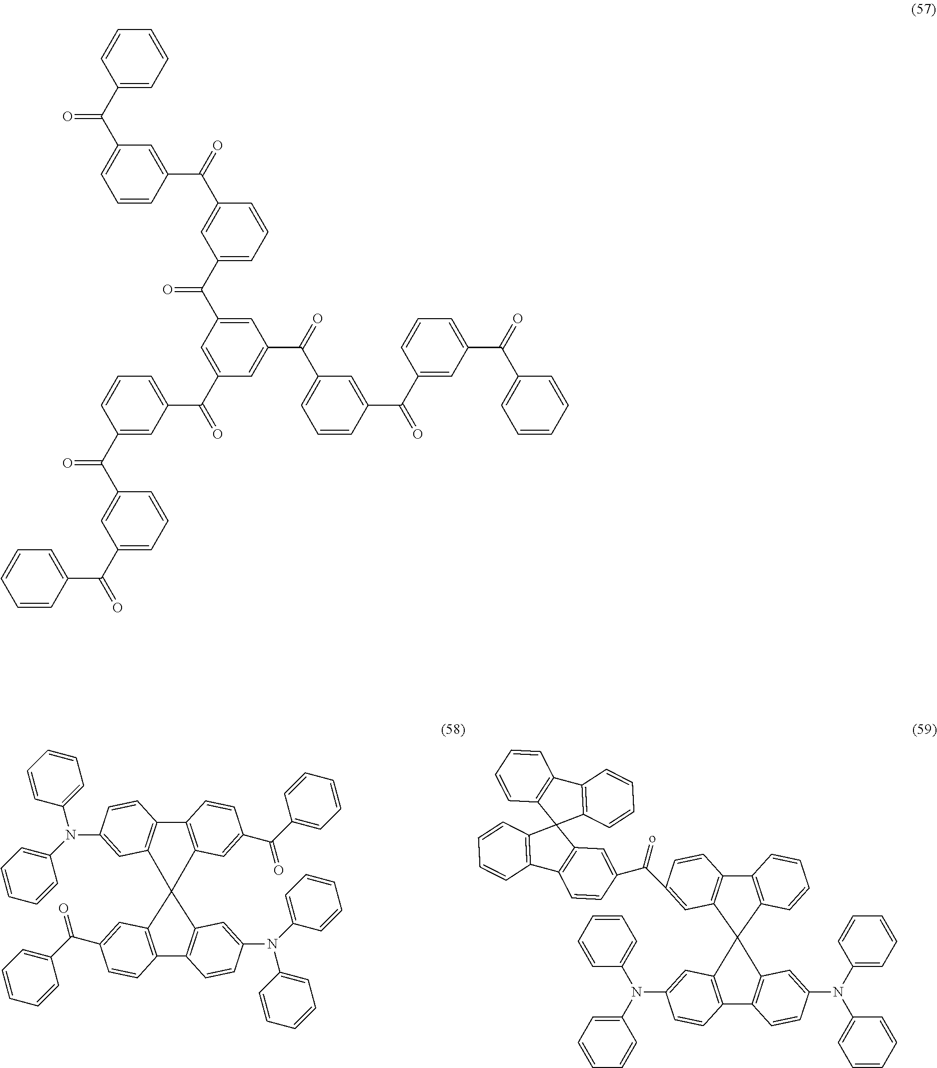

In accordance with the invention, the organic electroluminescent device furthermore comprises a hole-conducting compound in emitting layer B. Since, in particular, the position of the HOMO (highest occupied molecular orbital) is responsible for the hole-transport properties of the material, this compound preferably has an HOMO of >−5.8 eV, particularly preferably >−5.6 eV, very particularly preferably >−5.4 eV. The HOMO can be determined by photoelectron spectroscopy by means of a model AC-2 photoelectron spectrometer from Riken Keiki Co. Ltd. (http://www.rikenkeiki.com/pages/AC2.htm).

Preferred hole-conducting compounds are carbazole derivatives, for example CBP (N,N-biscarbazolylbiphenyl) or the carbazole derivatives disclosed in WO 05/039246, US 2005/0069729, JP 2004/288381, EP 1205527 or WO 08/086,851, triarylamine derivatives, indolocarbazole derivatives, for example in accordance with WO 07/063,754 or WO 08/056,746, azacarbazole derivatives, for example in accordance with EP 1617710, EP 1617711, EP 1731584, JP 2005/347160, bipolar matrix materials, for example in accordance with WO 07/137,725, phosphorescent metal complexes of the formulae (2) to (5) given above, if they have the above-mentioned condition for the HOMO and if they emit at a wavelength at least 20 nm shorter than the phosphorescent compound, and diazasilole or tetraazasilole derivatives, for example in accordance with the unpublished application DE 102008056688.8.

Apart from emission layer B according to the invention, which is described in greater detail above and which comprises a mixed host comprising hole-conducting compound and aromatic ketone, the organic electroluminescent device comprises at least two further emitting layers A and C. If the layer described above is a green-emitting layer, these are a blue-emitting layer and a red-emitting layer, each of which may comprise a fluorescent compound or a phosphorescent compound as emitting compound.

In a preferred embodiment of the invention, the red-emitting layer comprises at least one red-phosphorescent emitter. This is preferably selected from red-emitting structures of the formulae (2) to (5) mentioned above.

Suitable matrix materials for the red-phosphorescent emitter are selected from compounds of the formula (1) depicted above, for example in accordance with WO 04/013080, WO 04/093207, WO 06/005627 or the unpublished application DE 102008033943.1, triarylamines, carbazole derivatives, for example CBP (N,N-biscarbazolylbiphenyl) or the carbazole derivatives disclosed in WO 05/039246, US 2005/0069729, JP 2004/288381, EP 1205527 or WO 08/086,851, indolocarbazole derivatives, for example in accordance with WO 07/063,754 or WO 08/056,746, azacarbazoles, for example in accordance with EP 1617710, EP 1617711, EP 1731584, JP 2005/347160, bipolar matrix materials, for example in accordance with WO 07/137,725, silanes, for example in accordance with WO 05/111172, azaboroles or boronic esters, for example in accordance with WO 06/117052, triazine derivatives, for example in accordance with the unpublished application DE 102008036982.9, WO 07/063,754 or WO 08/056,746, and zinc complexes, for example in accordance with WO 09/062,578. Here too, it is possible to employ a plurality of different matrix materials as a mixture, in particular at least one electron-conducting matrix material and at least one hole-conducting matrix material.

In a preferred embodiment of the invention, the blue-emitting layer comprises at least one blue-phosphorescent emitter. This is preferably selected from blue-emitting structures of the formulae (2) to (5) given above.

In a further preferred embodiment of the invention, the blue-emitting layer comprises at least one blue-fluorescent emitter. Suitable blue-fluorescent emitters are selected, for example, from the group of the monostyrylamines, the distyrylamines, the tristyrylamines, the tetrastyrylamines, the styrylphosphines, the styryl ethers and the arylamines. A monostyrylamine is taken to mean a compound which contains one substituted or unsubstituted styryl group and at least one, preferably aromatic, amine. A distyrylamine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. For the purposes of this invention, an arylamine or aromatic amine is taken to mean a compound which contains three substituted or unsubstituted aromatic or heteroaromatic ring systems bonded directly to the nitrogen. At least one of these aromatic or heteroaromatic ring systems is preferably a condensed ring system, particularly preferably having at least 14 aromatic ring atoms. Preferred examples thereof are aromatic anthracenamines, aromatic pyrenamines, aromatic pyrenediamines, aromatic chrysenamines or aromatic chrysenediamines. An aromatic anthracenamine is taken to mean a compound in which a diarylamino group is bonded directly to an anthracene group, preferably in the 9-position or in the 2-position. Aromatic pyrenamines, pyrenediamines, chrysenamines and chrysenediamines are defined analogously thereto, where the diarylamino groups on the pyrene are preferably bonded in the 1-position or in the 1,6-position. Further preferred dopants are selected from indenofluorenamines or indenofluorenediamines, for example in accordance with WO 06/108497 or WO 06/122630, benzoindenofluorenamines or benzoindenofluorenediamines, for example in accordance with WO 08/006,449, and dibenzoindenofluorenamines or dibenzoindenofluorenediamines, for example in accordance with WO 07/140,847. Examples of dopants from the class of the styrylamines are substituted or unsubstituted tristilbenamines or the dopants described in WO 06/000388, WO 06/058737, WO 06/000389, WO 07/065,549 and WO 07/115,610. Still further preferred dopants are the condensed hydrocarbons disclosed in the unpublished application DE 102008035413.9.

Suitable host materials for the blue-fluorescent emitters, in particular for the above-mentioned emitters, are selected, for example, from the classes of the oligoarylenes (for example 2,2′,7,7-tetraphenylspirobifluorene in accordance with EP 676461 or dinaphthylanthracene), in particular the oligoarylenes containing condensed aromatic groups, the oligoarylenevinylenes (for example DPVBi or spiro-DPVBi in accordance with EP 676461), the polypodal metal complexes (for example in accordance with WO 04/081017), the hole-conducting compounds (for example in accordance with WO 04/058911), the electron-conducting compounds, in particular ketones, phosphine oxides, sulfoxides, etc. (for example in accordance with WO 05/084081 and WO 05/084082), the atropisomers (for example in accordance with WO 06/048268), the boronic acid derivatives (for example in accordance with WO 06/117052) and the benzanthracene derivatives (for example benz[a]anthracene derivatives in accordance with WO 08/145,239). Apart from the compounds according to the invention, particularly preferred host materials are selected from the classes of the oligoarylenes, containing naphthalene, anthracene, benzanthracene, in particular benz[a]anthracene and/or pyrene, or atropisomers of these compounds. For the purposes of this invention, an oligoarylene is intended to be taken to mean a compound in which at least three aryl or arylene groups are bonded to one another.

Apart from the cathode, anode and the at least three emitting layers which have been described above, the organic electroluminescent device may also comprise further layers which are not depicted in FIG. 1. These are selected, for example, from in each case one or more hole-injection layers, hole-transport layers, hole-blocking layers, electron-transport layers, electron-injection layers, electron-blocking layers, exciton-blocking layers, charge-generation layers (IDMC 2003, Taiwan; Session 21 OLED (5), T. Matsumoto, T. Nakada, J. Endo, K. Mori, N. Kawamura, A. Yokoi, J. Kido, Multiphoton Organic EL Device Having Charge Generation Layer) and/or organic or inorganic p/n junctions. In addition, interlayers may be present, which control, for example, the charge balance in the device. In particular, such interlayers may be appropriate as interlayers between two emitting layers, in particular as interlayer between a fluorescent layer and a phosphorescent layer. Furthermore, the use of more than three emitting layers may also be preferred. Furthermore, the layers, in particular the charge-transport layers, may also be doped. The doping of the layers may be advantageous for improved charge transport. However, it should be pointed out that each of these layers does not necessarily have to be present, and the choice of the layers is always dependent on the compounds used.

The use of layers of this type is known to the person skilled in the art, and he will be able, without inventive step, to use all materials in accordance with the prior art which are known for layers of this type for this purpose.

Preference is furthermore given to an organic electroluminescent device, characterised in that one or more layers are applied by means of a sublimation process, in which the materials are vapour-deposited in vacuum sublimation units at a pressure of less than 10⁻⁵ mbar, preferably less than 10⁻⁶ mbar. However, it should be noted that the pressure may also be even lower, for example less than 10⁻⁷ mbar.

Preference is likewise given to an organic electroluminescent device, characterised in that one or more layers are applied by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose. High solubility can be achieved through suitable substitution of the compounds. It is possible here not only for solutions of individual materials to be applied, but also solutions which comprise a plurality of compounds, for example matrix materials and dopants.

The organic electroluminescent device can also be produced as a hybrid system by applying one or more layers from solution and applying one or more other layers by vapour deposition.

These processes are generally known to the person skilled in the art and can be applied by him, without inventive step, to the organic electroluminescent devices according to the invention.

The invention furthermore relates to a method for setting the colour location of a white-emitting electroluminescent device which comprises at least three emitting layers A, B and C following one another in this sequence, where layer B comprises at least one phosphorescent emitter, at least one electron-conducting matrix material and at least one hole-conducting matrix material, characterised in that the colour location of the electroluminescent device is set by varying the mixing ratio of the hole-conducting matrix material and of the electron-conducting matrix material. The electron-conducting matrix material here is preferably an aromatic ketone, in particular a compound of the formula (1) given above, or a triazine derivative, preferably a triazine derivative which is substituted by three aromatic substituents.

The invention still furthermore relates to the use of a mixture of a hole-conducting matrix material and an electron-conducting matrix material in combination with a phosphorescent emitter in layer B of an organic electroluminescent device which comprises at least three emitting layers A, B and C following one another in this sequence, for setting the colour location of the organic electroluminescent device.

The organic electroluminescent devices according to the invention have the following surprising advantages over the prior art:
1. The colour location of the white-emitting organic electroluminescent device can be set simply and reproducibly with an accuracy of 0.01 (measured as CIE colour coordinates) by adjustment of the mixing ratio of the hole-conducting matrix material and of the aromatic ketone.
2. The organic electroluminescent device according to the invention has very high efficiency.
3. The organic electroluminescent device according to the invention simultaneously has a very good lifetime.

The invention is described in greater detail by the following examples, without wishing to restrict it thereby. The person skilled in the art will be able, without taking an inventive step, to produce further organic electroluminescent devices according to the invention and thus to carry out the invention throughout the range claimed.

### EXAMPLES

### Production and Characterisation of Organic Electroluminescent Devices

Electroluminescent devices according to the invention can be produced as described, for example, in WO 05/003253. The structures of the materials used are depicted below for clarity.

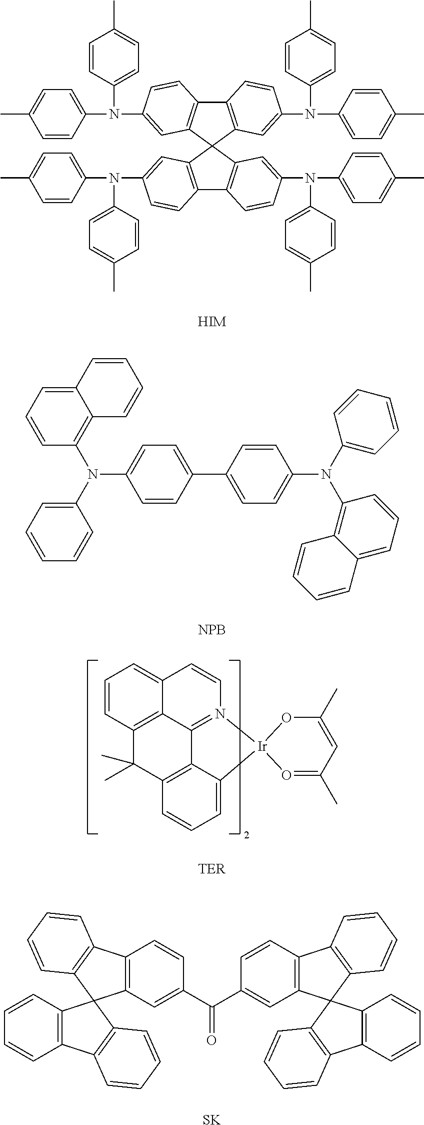

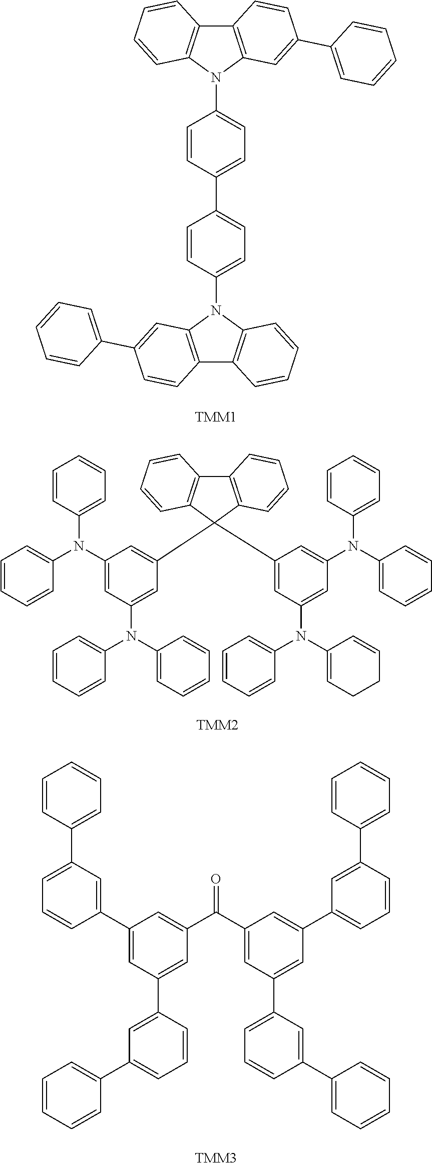

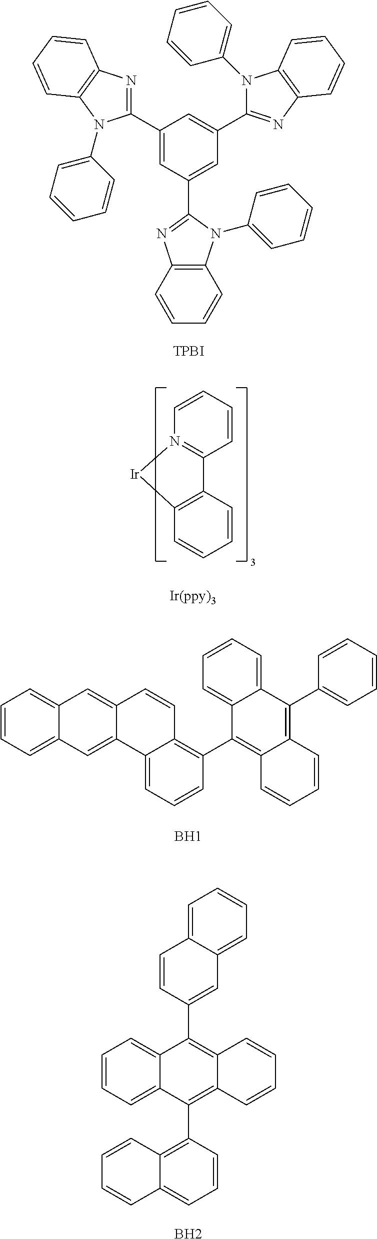

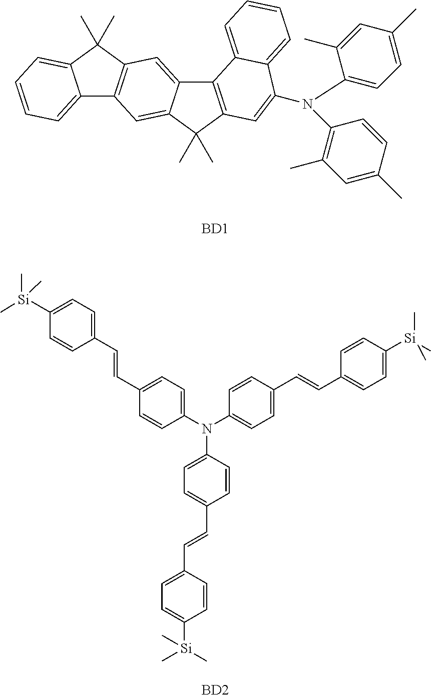

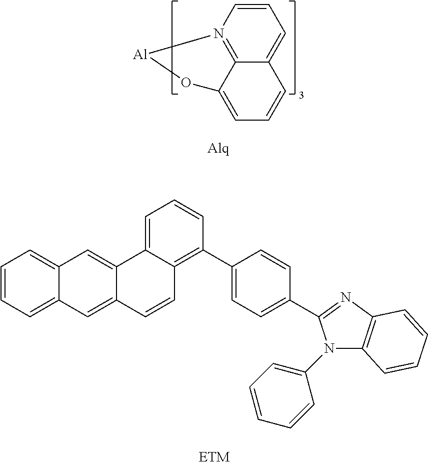

These as yet unoptimised OLEDs are characterised by standard methods; to this end, the electroluminescence spectra and colour coordinates (in accordance with CIE 1931), the efficiency (measured in cd/A) as a function of the luminance, the operating voltage, calculated from current-voltage-luminous density characteristic lines (IUL characteristic lines), and the lifetime are determined. The results obtained are shown in Table 1.

The results for various white OLEDs are compared below.

### Example 1

Examples 1a and 1b according to the invention are achieved through the following layer structure: 20 nm of HIM, 20 nm of NPB, 5 nm of NPB doped with 15% of TER, 15 nm of a mixed layer consisting of 75% of TMM1, 10% of SK and 15% of Ir(ppy)₃ (Example 1a) or 60% of TMM1, 25% of SK and 15% of Ir(ppy)₃ (Example 1b), 20 nm of BH doped with 5% of BD, 20 nm of Alq, 1 nm of LiF, 100 nm of Al. As can be seen from a direct comparison between Examples 1a and 1b, the use of the central mixed layer comprising two matrix materials enables the desired colour location to be set very comfortably. Both pure white with CIE 0.32/0.33 and also a very warm white with CIE 0.42/0.39 can be achieved merely by varying the concentration ratio of the two matrix materials in the mixed layer according to the invention.

Analogously thereto, every colour coordinate between those obtained in Examples 1a and 1b can be achieved through a suitable other choice of the mixing ratio. Variation or precise setting of the desired colour location is thus possible without other materials being required or another architecture parameter than the mixing ratio of the two matrix materials in the mixed layer having to be changed.

### Example 2

Examples 2a and 2b according to the invention are achieved through the following layer structure: 40 nm of HIM, 10 nm of TMM2 doped with 7% of TER, 10 nm of a mixed layer consisting of 70% of TMM2, 20% of TMM3 and 10% of Ir(ppy)₃ (Example 2a) or 50% of TMM2, 40% of TMM3 and 10% of Ir(ppy)₃ (Example 2b), 20 nm of BH2 doped with 5% of BD2, 20 nm of ETM, 1 nm of LiF, 100 nm of Al. In this case, the colour is varied in the warm-white region as is typically desired for lighting applications. While Example 2b with CIE 0.44/0.41 corresponds to the colour coordinates of illuminant A, a change in the mixing ratio in favour of TMM2 gives a less warm-white colour location of CIE 0.38/0.38.

### Example 3

### Comparison

This comparative example shows OLEDs which are built up from the same materials as Example 1, but without the use of a mixed host layer. Examples 3a and 3b are achieved through the following layer structure: 20 nm of HIM, 20 nm of NPB, 11 nm (3a) or 8 nm (3b) of BH1 doped with 5% of BD1, 17 nm (3a) or 18 nm (3b) of SK doped with 15% of Ir(ppy)₃, 12 nm (3a) or 14 nm (3b) of SK doped with 15% of TER, 20 nm of Alq, 1 nm of LiF, 100 nm of Al. Since the colour can no longer be set to white without the second matrix material in the green-emitting layer, the layer sequence here must be changed from red, green, blue to blue, green, red. The same pure- or warm-white colour coordinates are achieved corresponding to Examples 1a and 1b. Owing to the lack of adjustability of the mixed host layer, however, the colour here must be adjusted via layer-thickness variations in all three emitter layers, which means significantly higher technical complexity. In addition, it can be seen from the emission data that this type of architecture is inferior in efficiency and lifetime to that according to the invention from Example 1, although the same materials are used for the formation of the mixed matrix apart from the omission of TMM1.

### Example 4

### Comparison

Example 4 shows an OLED whose mixed layer comprises the material TPBI, which is not according to the invention, as electron-conducting component. The layer structure is, analogously to Example 1a, 20 nm of HIM, 20 nm of NPB, 5 nm of NPB doped with 15% of TER, 15 nm of a mixed layer consisting of 75% of TMM1, 10% of TPBI and 15% of Ir(ppy)₃ (Example 1a) or 60% of TMM1, 25% of SK and 15% of Ir(ppy)₃ (Example 1b), 20 nm of BH doped with 5% of BD, 20 nm of Alq, 1 nm of LiF, 100 nm of Al. On the one hand, it is evident that the colour coordinates are red-shifted compared with Example 1a. It is very difficult to achieve a pure-white colour using this material combination. In spite of a mixed layer which is already a very good hole conductor, it appears that insufficient holes move into the blue layer. On the other hand, the use of TPBI results in a significantly worse lifetime.

TABLE 1
Device results

| | | | | | | | Lifetime |
|---|---|---|---|---|---|---|---|
| | Composition of the | | | | | | 50% [h], |
| | layer with mixed | | | Efficiency | Voltage | | initial |
| | matrix | | | [cd/A] at | [V] at | | luminance |
| Ex. | Host 1 | Host 2 | Dopant | 1000 cd/m² | 1000 cd/m² | CIE x/y | 1000 cd/m² |
| 1a | TMM1 (75%) | SK (10%) | Ir(ppy)₃ | 13 | 5.2 | 0.32/0.33 | 10000 |
| | | | (15%) | | | | |
| 1b | TMM1 (60%) | SK (25%) | Ir(ppy)₃ | 18 | 5.5 | 0.42/0.39 | 8000 |
| | | | (15%) | | | | |
| 2a | TMM2 (70%) | TMM3 (20%) | Ir(ppy)₃ | 22 | 4.5 | 0.39/0.38 | 3000 |
| | | | (10%) | | | | |
| 2b | TMM2 (50%) | TMM3 (40%) | Ir(ppy)₃ | 27 | 4.4 | 0.44/0.41 | 4000 |
| | | | (10%) | | | | |
| 3a | SK (85%) | | Ir(ppy)₃ | 11 | 5.5 | 0.32/0.33 | 6000 |
| (comp.) | | | (15%) | | | | |
| 3b | SK (85%) | | Ir(ppy)₃ | 13 | 5.1 | 0.42/0.39 | 5000 |
| (comp.) | | | (15%) | | | | |
| 4 | TMM1 (75%) | TPBI (10%) | Ir(ppy)₃ | 13 | 5.1 | 0.35/0.33 | 2000 |
| (comp.) | | | (15%) | | | | |

1-15. (canceled)

16. An organic electroluminescent device comprising an anode, a cathode and at least three emitting layers A, B and C following one another in this sequence, wherein emitting layer B, which is located between layers A and C, comprises at least one phosphorescent compound, at least one hole-conducting material, and at least one aromatic ketone.

17. The organic electroluminescent device claim 16, wherein it is a white-emitting organic electroluminescent device.

18. The organic electroluminescent device claim 16, wherein said aromatic ketone is a compound of formula (1): 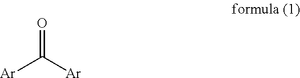
wherein
Ar is on each occurrence, identically or differently, an aromatic or heteroaromatic ring system having 5 to 80 aromatic ring atoms, which in each case are optionally substituted by one or more groups R¹;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a branched or cyclic alkyl, alkoxy or thioalkoxy group having 3 to 40 C atoms or an alkenyl or alkynyl group having 2 to 40 C atoms, each of which are optionally substituted by one or more radicals R², wherein one or more non-adjacent CH₂ groups are optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR², and wherein one or more H atoms are optionally replaced by F, Cl, Br, I, CN or NO₂, an aromatic or heteroaromatic ring system having 5 to 60 aromatic ring atoms, which in each case are optionally substituted by one or more radicals R², an aryloxy or heteroaryloxy group having 5 to 60 aromatic ring atoms optionally substituted by one or more radicals R², an aralkyl or heteroaralkyl group having 5 to 60 aromatic ring atoms optionally substituted by one or more radicals R², or a combination of these systems; and wherein two or more adjacent substituents R¹ optionally define a mono- or polycyclic, aliphatic or aromatic ring system with one another;
Ar¹ is on each occurrence, identically or differently, an aromatic or heteroaromatic ring system having 5 to 40 aromatic ring atoms optionally substituted by one or more radicals R²;
R² is on each occurrence, identically or differently, H, D, CN or an aliphatic, aromatic and/or heteroaromatic organic radical having 1 to 20 C atoms, wherein H atoms are optionally replaced by F; and wherein two or more adjacent substituents R² optionally define a mono- or polycyclic, aliphatic or aromatic ring system with one another.

19. The organic electroluminescent device of claim 18, wherein Ar is phenyl, 2-, 3- or 4-tolyl, 3- or 4-o-xylyl, 2- or 4-m-xylyl, 2-p-xylyl, o-, m- or p-tert-butylphenyl, o-, m- or p-fluorophenyl, benzophenone, 1-, 2- or 3-phenylmethanone, 2-, 3- or 4-biphenyl, 2-, 3- or 4-o-terphenyl, 2-, 3- or 4-m-terphenyl, 2-, 3- or 4-p-terphenyl, 2′-p-terphenyl, 2′-, 4′- or 5′-m-terphenyl, 3′- or 4′-o-terphenyl, p-, m,p-, o,p-, m,m-, o,m- or o,o-quaterphenyl, quinquephenyl, sexiphenyl, 1-, 2-, 3- or 4-fluorenyl, 2-, 3- or 4-spiro-9,9′-bifluorenyl, 1-, 2-, 3- or 4-(9,10-dihydro)phenanthrenyl, 1- or 2-naphthyl, 2-, 3-, 4-, 5-, 6-, 7- or 8-quinolinyl, 1-, 3-, 4-, 5-, 6-, 7- or 8-isoquinolinyl, 1- or 2-(4-methylnaphthyl), 1- or 2-(4-phenylnaphthyl), 1- or 2-(4-naphthyl-naphthyl), 1-, 2- or 3-(4-naphthyl-phenyl), 2-, 3- or 4-pyridyl, 2-, 4- or 5-pyrimidinyl, 2- or 3-pyrazinyl, 3- or 4-pyridanzinyl, 2-(1,3,5-triazin)yl-, 2-, 3- or 4-(phenylpyridyl), 3-, 4-, 5- or 6-(2,2′-bipyridyl), 2-, 4-, 5- or 6-(3,3′-bipyridyl), 2- or 3-(4,4′-bipyridyl) and combinations of one or more of these radicals.

20. The organic electroluminescent device of claim 16, wherein the three emitting layers A, B and C are a red-emitting layer, a green-emitting layer and a blue-emitting layer.

21. The organic electroluminescent device of claim 20, wherein layer A is a red-emitting layer, layer B is a green-emitting layer and layer C is a blue-emitting layer, where layer A is on the anode side and layer C is on the cathode side, or in that layer A is a blue-emitting layer, layer B is a green-emitting layer and layer C is a red-emitting layer, where layer A is on the anode side and layer C is on the cathode side.

22. The organic electroluminescent device of claim 16, wherein the proportion of the phosphorescent compound in layer B is 1 to 50% by volume.

23. The organic electroluminescent device of claim 16, wherein the mixing ratio between the hole-conducting compound and the aromatic ketone is in the range of from 20:1 to 1:10.

24. The organic electroluminescent device of claim 16, wherein the phosphorescent emitter present is at least one compound of formulae (2) to (5): 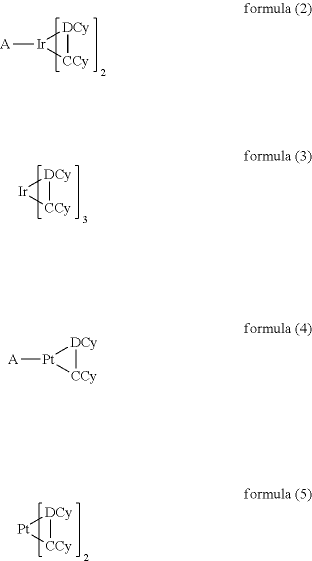
wherein
R¹ is as defined in claim 18;
DCy is, identically or differently on each occurrence, a cyclic group which contains at least one donor atom via which the cyclic group is bonded to the metal, and which optionally carry one or more substituents R¹; and wherein the groups DCy and CCy are bonded to one another via a covalent bond;
CCy is, identically or differently on each occurrence, a cyclic group which contains a carbon atom via which the cyclic group is bonded to the metal and which optionally carry one or more substituents R¹;
A is, identically or differently on each occurrence, a monoanionic, bidentate-chelating ligand, preferably a diketonate ligand or a piccolinate ligand.

25. The organic electroluminescent device of claim 16, wherein the hole-conducting compound in layer B has an HOMO of >−5.8 eV.

26. The organic electroluminescent device of claim 16, wherein the hole-conducting compound used in layer B is a carbazole derivative, triarylamine derivative, indolocarbazole derivative, azacarbazole derivative, bipolar matrix material, phosphorescent metal complex of the formulae (2) to (5) according to claim 24 or diazasilole or tetraazasilole derivative.

27. The organic electroluminescent device of claim 16, wherein the red-emitting layer comprises at least one red-phosphorescent emitter and the matrix material used for the red-phosphorescent emitter is a compound of formula (1) as defined in claim 18 or 19, triarylamine, carbazole derivative, indolocarbazole derivative, azacarbazole derivative, bipolar matrix material, silane, azaborole, boronic ester, triazine derivative, zinc complex or a mixture of these materials.

28. The organic electroluminescent device of claim 16, wherein the blue-emitting layer comprises at least one blue-phosphorescent emitter or at least one blue-fluorescent emitter, wherein the host material for the blue-fluorescent emitter is selected from the classes of the oligoarylenes.

29. A method for setting the colour location of a white-emitting electroluminescent device which comprises at least three emitting layers A, B and C following one another in this sequence, where layer B comprises at least one phosphorescent emitter, at least one electron-conducting matrix material and at least one hole-conducting matrix material, comprising the step of setting the colour location of the electroluminescent device by varying the mixing ratio of the hole-conducting matrix material and of the electron-conducting matrix material.
